(19) United States
(12) Patent Application Publication
(10) Pub. No.: US 2026/0197932 A1
(43) Pub. Date: Jul. 9, 2026

(54) MULTILAYER SUBSTRATE

(71) Applicant: Murata Manufacturing Co., Ltd., Nagaokakyo-shi (JP)

(72) Inventor: Kenji MATSUDA, Nagaokakyo-shi (JP)

(21) Appl. No.: 19/558,734

(22) Filed: Mar. 6, 2026

Related U.S. Application Data
(63) Continuation of application No. PCT/JP2024/031851, filed on Sep. 5, 2024.

(30) Foreign Application Priority Data
Oct. 4, 2023 (JP) 2023-172566

(51) Int. Cl. H05K 1/02; H05K 1/03

(52) U.S. Cl. CPC H05K 1/0218; H05K 1/0237; H05K 1/032; H05K 2201/0141; H05K 2201/015

(57) ABSTRACT

In a multilayer substrate, ground electrodes are spaced apart from each other in a thickness direction of a laminate substrate and are adjacent to signal lines in a width direction of the signal lines. In a first transmission line region in which a maximum line width of the signal lines is smallest, the signal lines do not overlap any of the ground electrodes in the thickness direction of the laminate substrate. In a second transmission line region in which the maximum line width of the signal lines is largest, one ground electrode among the ground electrodes overlaps the signal lines other than the signal line adjacent to the one ground electrode among the signal lines.

### CROSS REFERENCE TO RELATED APPLICATIONS

This application claims the benefit of priority to Japanese Patent Application No. 2023-172566 filed on Oct. 4, 2023 and is a Continuation Application of PCT Application No. PCT/JP2024/031851 filed on Sep. 5, 2024. The entire contents of each application are hereby incorporated herein by reference.

### BACKGROUND OF THE INVENTION

### 1. Field of the Invention

The present invention generally relates to multilayer substrates, and more particularly to multilayer substrates each including an alternating current signal line.

### 2. Description of the Related Art

International Publication No. WO 2023/037852 discloses a multilayer substrate including a multilayer body (laminate substrate), three signal conductors (signal lines), and six ground conductors.

The multilayer body has a structure in which a plurality of resin layers (insulating layers) are laminated in a lamination direction. The positions of the three signal conductors in the lamination direction are different. The three signal conductors are electrically connected. In the multilayer substrate disclosed in International Publication No. WO 2023/037852, in plan view from the lamination direction, the ground conductors are located on both sides of each of the three signal conductors in a width direction. A high frequency signal is transmitted through the three signal conductors.

In the multilayer substrate disclosed in International Publication No. WO 2023/037852, because the ground conductors are located on both sides of each of the three signal conductors in the width direction, due to a proximity effect, current concentrates at both end portions of each of the three signal conductors in the width direction, resulting in high alternating current resistance.

### SUMMARY OF THE INVENTION

Example embodiments of the present invention provide multilayer substrates each with reduced alternating current resistance.

A multilayer substrate according to an example embodiment of the present invention includes a laminate substrate, an alternating current signal line, and a plurality of ground electrodes. A plurality of insulating layers are laminated in the laminate substrate. The alternating current signal line is provided in the laminate substrate. The alternating current signal line includes a plurality of signal lines spaced apart from each other in a thickness direction of the laminate substrate, and the plurality of signal lines are electrically connected by a plurality of connection conductors that penetrate one of the plurality of insulating layers in the thickness direction. The plurality of ground electrodes are provided in the laminate substrate. The plurality of ground electrodes are spaced apart from each other in the thickness direction and are adjacent to the plurality of signal lines in a width direction of the plurality of signal lines. In a first transmission line region in which a maximum line width of the plurality of signal lines is smallest, the plurality of signal lines do not overlap any of the plurality of ground electrodes in the thickness direction. In a second transmission line region in which the maximum line width of the plurality of signal lines is largest, one ground electrode among the plurality of ground electrodes overlaps a signal line other than a signal line adjacent to the one ground electrode among the plurality of signal lines.

The multilayer substrates according to example embodiments of the present invention each have alternating current resistance.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a plan view of a portion of a multilayer substrate according to example embodiment 1 of the present invention.

FIG. 2 relates to the multilayer substrate according to example embodiment 1 of the present invention, and is a sectional view taken along line II-II in FIG. 1.

FIG. 3 relates to the multilayer substrate according to example embodiment 1 of the present invention, and is a sectional view taken along line III-III in FIG. 1.

FIG. 4 is a plan view showing both transmission line regions and mounting regions in the multilayer substrate according to example embodiment 1 of the present invention.

FIG. 5 relates to the multilayer substrate according to example embodiment 1 of the present invention, and is a graph indicating a relationship between alternating current resistance and a signal line width.

FIG. 6 is a plan view of a portion of a multilayer substrate according to example embodiment 2 of the present invention.

FIG. 7 relates to the multilayer substrate according to example embodiment 2 of the present invention, and is a sectional view taken along line VII-VII in FIG. 6.

FIG. 8 relates to the multilayer substrate according to example embodiment 2 of the present invention, and is a sectional view taken along line VIII-VIII in FIG. 6.

FIG. 9 is a plan view of a portion of a multilayer substrate according to example embodiment 3 of the present invention.

FIG. 10 relates to the multilayer substrate according to example embodiment 3 of the present invention, and is a sectional view taken along line X-X in FIG. 9.

FIG. 11 relates to the multilayer substrate according to example embodiment 3 of the present invention, and is a sectional view taken along line XI-XI in FIG. 9.

FIG. 12 is a plan view of a portion of a multilayer substrate according to example embodiment 4 of the present invention.

FIG. 13 relates to the multilayer substrate according to example embodiment 4 of the present invention, and is a sectional view taken along line XIII-XIII in FIG. 12.

FIG. 14 relates to the multilayer substrate according to example embodiment 4 of the present invention, and is a sectional view taken along line XIV-XIV in FIG. 12.

FIG. 15 is a plan view of a portion of a multilayer substrate according to example embodiment 5 of the present invention.

FIG. 16 relates to the multilayer substrate according to example embodiment 5 of the present invention, and is a sectional view taken along line XVI-XVI in FIG. 15.

FIG. 17 relates to the multilayer substrate according to example embodiment 5 of the present invention, and is a sectional view taken along line XVII-XVII in FIG. 15.

FIG. 18 is a plan view of a portion of a multilayer substrate according to example embodiment 6 of the present invention.

FIG. 19 is a plan view showing, in a see-through manner, a second signal line, a second ground electrode, and an RF signal line in the multilayer substrate according to example embodiment 6 of the present invention.

FIG. 20 relates to the multilayer substrate according to example embodiment 6 of the present invention, and is a sectional view taken along line XX-XX in FIG. 18.

FIG. 21 relates to the multilayer substrate according to example embodiment 6 of the present invention, and is a sectional view taken along line XXI-XXI in FIG. 18.

FIG. 22 is a plan view of a portion of a multilayer substrate according to example embodiment 7 of the present invention.

FIG. 23 is a plan view showing, in a see-through manner, the second signal line, the second ground electrode, and the RF signal line in the multilayer substrate according to example embodiment 7 of the present invention.

FIG. 24 relates to the multilayer substrate according to example embodiment 7 of the present invention, and is a sectional view taken along line XXIV-XXIV in FIG. 22.

FIG. 25 relates to the multilayer substrate according to example embodiment 7 of the present invention, and is a sectional view taken along line XXV-XXV in FIG. 22.

FIG. 26 is a sectional view of a multilayer substrate according to example embodiment 8 of the present invention.

FIG. 27 is a plan view of a portion of a multilayer substrate according to example embodiment 9 of the present invention.

FIG. 28 is a plan view showing, in a see-through manner, the second signal line, the second ground electrode, and the RF signal line in the multilayer substrate according to example embodiment 9 of the present invention.

FIG. 29 relates to the multilayer substrate according to example embodiment 9 of the present invention, and is a sectional view taken along line XXIX-XXIX in FIG. 27.

FIG. 30 relates to the multilayer substrate according to example embodiment 9 of the present invention, and is a sectional view taken along line XXX-XXX in FIG. 27.

FIG. 31 is a plan view of a portion of a multilayer substrate according to example embodiment 10 of the present invention.

FIG. 32 relates to the multilayer substrate according to example embodiment 10 of the present invention, and is a sectional view taken along line XXXII-XXXII in FIG. 31.

FIG. 33 relates to the multilayer substrate according to example embodiment 10 of the present invention, and is a sectional view taken along line XXXIII-XXXIII in FIG. 31.

FIG. 34 relates to the multilayer substrate according to example embodiment 10 of the present invention, and is a see-through plan view of a major portion for explaining a position of a connection conductor in the vicinity of a boundary region between a first transmission line region and a second transmission line region.

FIG. 35 is a plan view of a portion of a multilayer substrate according to example embodiment 11 of the present invention.

FIG. 36 relates to the multilayer substrate according to example embodiment 11 of the present invention, and is a sectional view taken along line XXXVI-XXXVI in FIG. 35.

FIG. 37 relates to the multilayer substrate according to example embodiment 11 of the present invention, and is a sectional view taken along line XXXVII-XXXVII in FIG. 35.

### DETAILED DESCRIPTION OF THE EXAMPLE EMBODIMENTS

Example embodiments 1 to 11 of the present invention and the like are described below with reference to the drawings. The drawings referred to in the following example embodiments 1 to 11 and the like are schematic diagrams, and the sizes and thicknesses of components in the drawings do not necessarily reflect actual dimensions. Further, the ratios of sizes and the ratios of thicknesses among the components also do not necessarily reflect actual dimensional ratios.

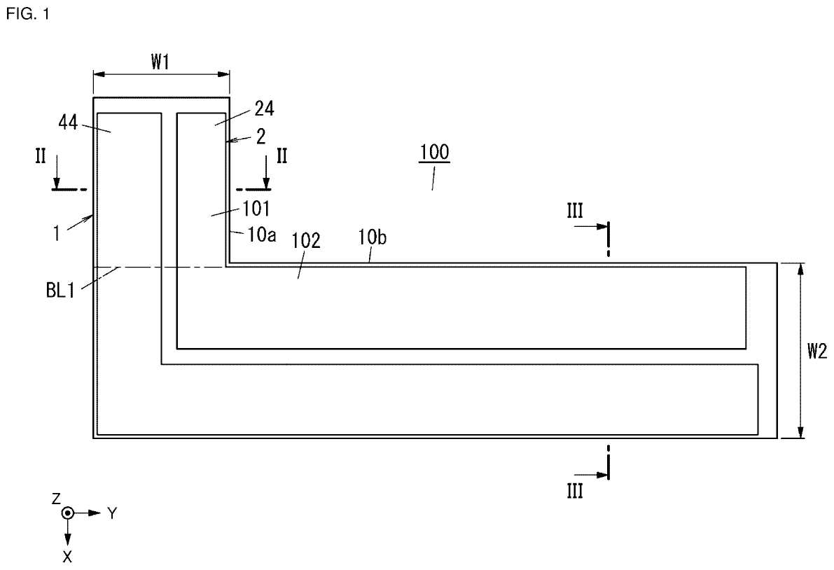

A multilayer substrate 100 according to example embodiment 1 of the present invention is described with reference to FIGS. 1 to 5.

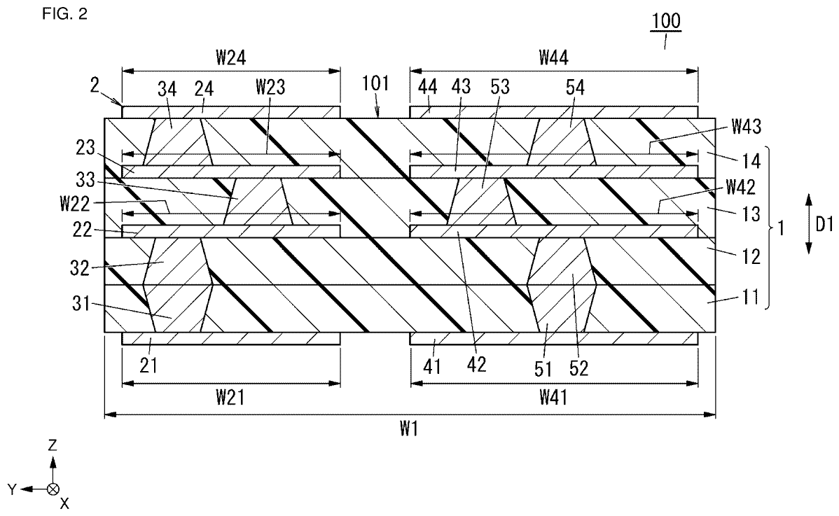

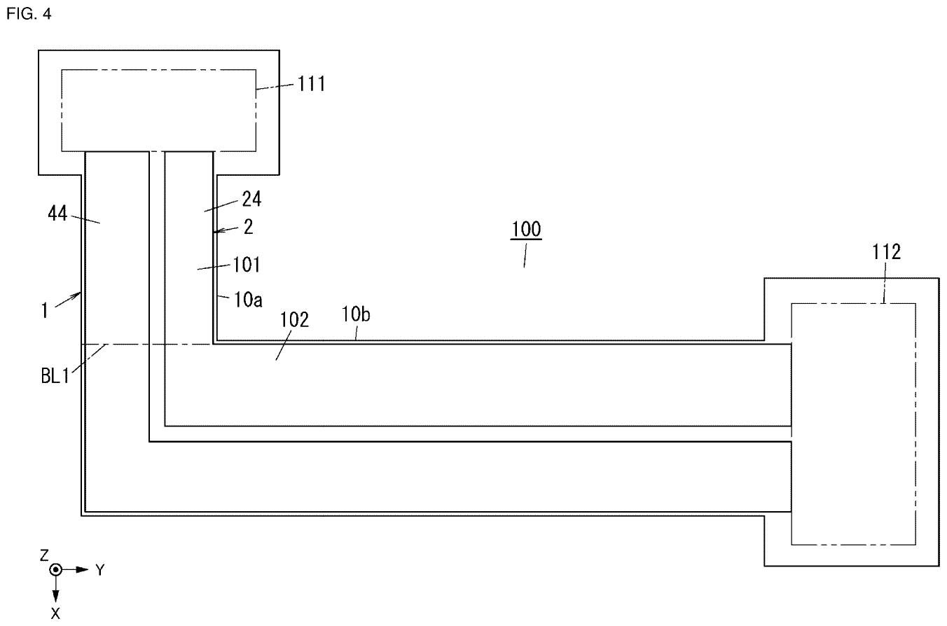

As shown in FIGS. 1 to 3, the multilayer substrate 100 according to example embodiment 1 includes a laminate substrate 1, an alternating current signal line 2, and a plurality of (four, in the example of FIG. 2) ground electrodes 41 to 44. For example, as shown in FIG. 4, the multilayer substrate 100 includes a first transmission line region 101, a second transmission line region 102, a first mounting region 111, and a second mounting region 112. However, in FIG. 1, portions of the multilayer substrate 100 including the first mounting region 111 and the second mounting region 112 are omitted. In FIGS. 1 and 4, a boundary BL1 between the first transmission line region 101 and the second transmission line region 102 is shown by a dash-dot line. However, this boundary BL1 is a virtual boundary provided for description. The first mounting region 111 is a region in which a first electronic component (for example, connector) to which a first end of the alternating current signal line 2 and a first end of each of the ground electrodes 41 to 44 are connected is provided. That the first electronic component is provided in the first mounting region 111 includes mechanical connection of the first electronic component to the multilayer substrate 100 and electrical connection of the first electronic component to the alternating current signal line 2. The second mounting region 112 is a region in which a second electronic component (for example, a connector) to which a second end of the alternating current signal line 2 and a second end of each of the ground electrodes 41 to 44 are connected is provided. That the second electronic component is provided includes mechanical connection of the second electronic component to the multilayer substrate 100 and electrical connection of the second electronic component to the alternating current signal line 2.

In each of FIGS. 1 to 4, a Cartesian coordinate system including three axes of an X-axis, a Y-axis, and a Z-axis orthogonal or substantially orthogonal to each other is defined, and an axis along a thickness direction D1 (see FIG. 2) of the laminate substrate 1 is indicated as the Z-axis. The X-axis, the Y-axis, and the Z-axis are all virtual axes. Arrows indicating “X,” “Y,” and “Z” in the drawings are merely shown for description, and none of them are associated with a physical entity. The multilayer substrate 100 is, for example, a flexible substrate. In the example of FIG. 1, the thickness direction D1 of the multilayer substrate 100 is a direction along the Z-axis. However, when the multilayer substrate 100 is bent, the thickness direction D1 differs depending on a position of the multilayer substrate 100.

The multilayer substrate 100 is, for example, housed in a housing of electronic equipment. The electronic equipment is, for example, a communication device. The communication device is, for example, a mobile phone (for example, smartphone), but is not limited to a mobile phone, and may be, for example, a notebook personal computer, a wearable terminal (for example, smartwatch), or the like.

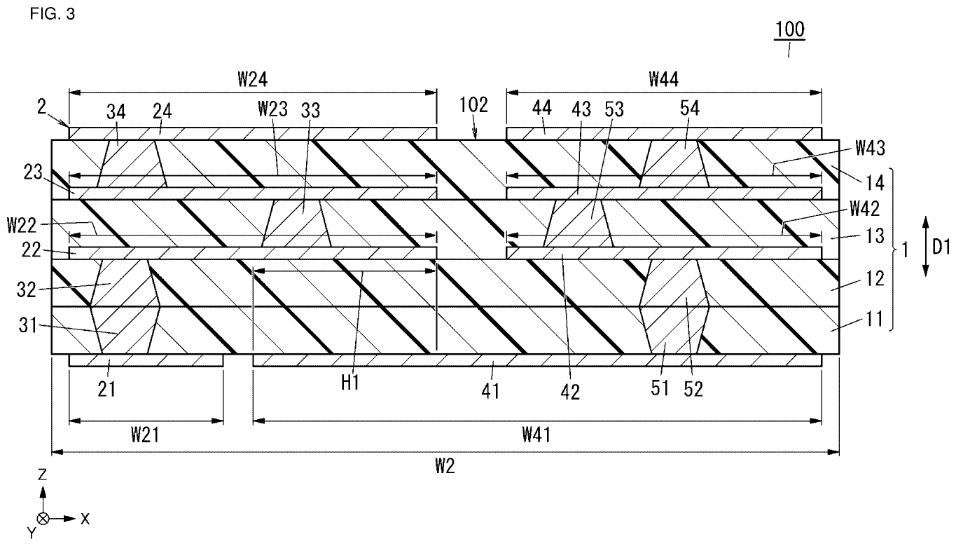

As shown in FIGS. 2 and 3, the laminate substrate 1 includes a plurality of (four, in the example of FIGS. 2 and 3) insulating layers 11, 12, 13, and 14, and the insulating layers 11, 12, 13, and 14 are laminated. The thickness direction D1 of the laminate substrate 1 is a lamination direction of the insulating layers 11, 12, 13, and 14. Hereinafter, for convenience of description, the insulating layer 11, the insulating layer 12, the insulating layer 13, and the insulating layer 14 are sometimes referred to as the first insulating layer 11, the second insulating layer 12, the third insulating layer 13, and the fourth insulating layer 14, respectively.

In the laminate substrate 1, the first insulating layer 11, the second insulating layer 12, the third insulating layer 13, and the fourth insulating layer 14 are laminated in order of the first insulating layer 11, the second insulating layer 12, the third insulating layer 13, and the fourth insulating layer 14.

A material of each of the insulating layers 11, 12, 13, and 14 includes, for example, a thermoplastic resin. The thermoplastic resin is, for example, a liquid crystal polymer. The thermoplastic resin is not limited to a liquid crystal polymer, and may be, for example, polytetrafluoroethylene (PTFE). In the present example embodiment, the first insulating layer 11 and the second insulating layer 12 are made to self-adhere to each other, and an adhesive layer is not interposed between the first insulating layer 11 and the second insulating layer 12. Further, in the present example embodiment, the second insulating layer 12 and the third insulating layer 13 are made to self-adhere to each other, and an adhesive layer is not interposed between the second insulating layer 12 and the third insulating layer 13. Further, in the present example embodiment, the third insulating layer 13 and the fourth insulating layer 14 are made to self-adhere to each other, and an adhesive layer is not interposed between the third insulating layer 13 and the fourth insulating layer 14.

A thickness of each of the insulating layers 11, 12, 13, and 14 is, for example, about 10 μm or more and about 120 μm or less.

In the present example embodiment, in plan view from the thickness direction D1 of the laminate substrate 1, the laminate substrate 1 has, for example, an L-shape. In the example of FIG. 1, the laminate substrate 1 has a rectangular or substantially rectangular first portion 10a in which a length in a direction along the X-axis is longer than a length in a direction along the Y-axis, and an elongated second portion 10b in which a length in a direction along the Y-axis is longer than a length in a direction along the X-axis.

As shown in FIG. 1, the alternating current signal line 2 is provided in the laminate substrate 1. The alternating current signal line 2 is a line through which a signal is transmitted. In the present disclosure, the alternating current signal line 2 is a line through which a signal whose magnitude changes with time is transmitted. The alternating current signal line 2 is, for example, a near field communication (NFC) signal line. In the present example embodiment, a signal transmitted through the alternating current signal line 2 is an alternating current signal having a frequency of, for example, about 13.56 MHz. The alternating current signal line 2 is not limited to an NFC signal line, and may be a digital signal line or a differential line, for example.

As shown in FIGS. 2 and 3, the alternating current signal line 2 includes a plurality of signal lines (signal electrodes) 21, 22, 23, and 24 spaced apart from each other in the thickness direction D1 of the laminate substrate 1. In plan view from the thickness direction D1 of the laminate substrate 1, the signal lines 21, 22, 23, and 24 overlap each other. Hereinafter, for convenience of description, the signal line 21, the signal line 22, the signal line 23, and the signal line 24 are sometimes referred to as the first signal line 21, the second signal line 22, the third signal line 23, and the fourth signal line 24, respectively.

The signal lines 21, 22, 23, and 24 have line widths W21, W22, W23, and W24, respectively.

Each of the signal lines 21 to 24 has conductivity. A material of each of the signal lines 21 to 24 includes, for example, copper.

A thickness of each of the signal lines 21 to 24 is, for example, about 3 μm or more and about 40 μm or less. The thickness of each of the signal lines 21 to 24 is thinner than the thickness of each of the insulating layers 11 to 14.

The first signal line 21 is laminated on the first insulating layer 11. The second signal line 22 is laminated on the second insulating layer 12. The third signal line 23 is laminated on the third insulating layer 13. The fourth signal line 24 is laminated on the fourth insulating layer 14. In the multilayer substrate 100, the first signal line 21, the first insulating layer 11, the second insulating layer 12, the second signal line 22, the third insulating layer 13, the third signal line 23, the fourth insulating layer 14, and the fourth signal line 24 are laminated in order of the first signal line 21, the first insulating layer 11, the second insulating layer 12, the second signal line 22, the third insulating layer 13, the third signal line 23, the fourth insulating layer 14, and the fourth signal line 24.

Each of the signal lines 21 to 24 is arranged in a predetermined pattern. In the present example embodiment, in plan view from the thickness direction D1 of the laminate substrate 1, each of the signal lines 21 to 24 has an L-shape, for example. The first signal line 21 is formed, for example, by patterning a copper foil (hereinafter, also referred to as first copper foil) applied to the first insulating layer 11. The second signal line 22 is formed, for example, by patterning a copper foil (hereinafter, also referred to as second copper foil) applied to the second insulating layer 12. The third signal line 23 is formed, for example, by patterning a copper foil (hereinafter, also referred to as third copper foil) applied to the third insulating layer 13. The fourth signal line 24 is formed, for example, by patterning a copper foil (hereinafter, also referred to as fourth copper foil) applied to the fourth insulating layer 14.

Further, the alternating current signal line 2 includes a plurality of connection conductors that electrically connect the signal lines 21 to 24. Each of the connection conductors is an interlayer connection conductor that connects the signal lines provided on two insulating layers different from each other among the insulating layers 11 to 14. Each of the connection conductors has conductivity. In the alternating current signal line 2, the signal lines 21 to 24 are electrically connected by the connection conductors that penetrate one of the insulating layers 11 to 14 in the thickness direction D1 of the laminate substrate 1. The connection conductors include a plurality of first connection conductors 31 penetrating the first insulating layer 11, a plurality of second connection conductors 32 penetrating the second insulating layer 12, a plurality of third connection conductors 33 penetrating the third insulating layer 13, and a plurality of fourth connection conductors 34 penetrating the fourth insulating layer 14. In the present example embodiment, the first connection conductors 31 and the second connection conductors 32 correspond to each other on a one-to-one basis, and the first connection conductor 31 and the second connection conductor 32 corresponding to each other overlap in the thickness direction D1 of the laminate substrate 1 and are electrically connected.

In the present example embodiment, the first connection conductors 31 overlap the first signal line 21 in the thickness direction D1 of the laminate substrate 1. The first connection conductors 31 are spaced apart from each other in a length direction of the first signal line 21. The length direction of the first signal line 21 is a direction along the first signal line 21, and is a direction orthogonal or substantially orthogonal to a width direction (line width direction) of the first signal line 21, and is a direction in which a signal is transmitted in the first signal line 21. Further, the second connection conductors 32 overlap the second signal line 22 in the thickness direction D1 of the laminate substrate 1. The second connection conductors 32 are spaced apart from each other in a length direction of the second signal line 22. The length direction of the second signal line 22 is a direction along the second signal line 22, and is a direction orthogonal or substantially orthogonal to a width direction (line width direction) of the second signal line 22, and is a direction in which a signal is transmitted in the second signal line 22. In the present example embodiment, the first signal line 21 and the second signal line 22 are electrically connected to each other by the first connection conductors 31 and the second connection conductors 32.

Further, the third connection conductors 33 overlap the third signal line 23 in the thickness direction D1 of the laminate substrate 1. The third connection conductors 33 are spaced apart from each other in a length direction of the third signal line 23. The length direction of the third signal line 23 is a direction along the third signal line 23, and is a direction orthogonal or substantially orthogonal to a width direction (line width direction) of the third signal line 23, and is a direction in which a signal is transmitted in the third signal line 23. In the present example embodiment, the second signal line 22 and the third signal line 23 are electrically connected to each other by the third connection conductors 33.

Further, the fourth connection conductors 34 overlap the fourth signal line 24 in the thickness direction D1 of the laminate substrate 1. The fourth connection conductors 34 are spaced apart from each other in a length direction of the fourth signal line 24. The length direction of the fourth signal line 24 is a direction along the fourth signal line 24, and is a direction orthogonal or substantially orthogonal to a width direction (line width direction) of the fourth signal line 24, and is a direction in which a signal is transmitted in the fourth signal line 24. In the present example embodiment, the third signal line 23 and the fourth signal line 24 are electrically connected to each other by the fourth connection conductors 34.

Each of the first connection conductors 31, the second connection conductors 32, the third connection conductors 33, and the fourth connection conductors 34 has conductivity. Each of the first connection conductors 31, the second connection conductors 32, the third connection conductors 33, and the fourth connection conductors 34 includes, for example, copper, a copper-tin alloy, or a resin. The first connection conductors 31 are formed, for example, by filling a plurality of via-holes formed in the first insulating layer 11 with conductive paste including copper, a low-melting-point metal (for example, tin), and a resin and heating the conductive paste in a state in which each of the via-holes is closed by a portion of the first copper foil. The second connection conductors 32 are formed, for example, by filling a plurality of via-holes formed in the second insulating layer 12 with conductive paste including copper, a low-melting-point metal (for example, tin), and a resin and heating the conductive paste in a state in which each of the via-holes is closed by a portion of the second copper foil. The third connection conductors 33 are formed, for example, by filling a plurality of via-holes formed in the third insulating layer 13 with conductive paste including copper, a low-melting-point metal (for example, tin), and a resin and heating the conductive paste in a state in which each of the via-holes is closed by a portion of the third copper foil. The fourth connection conductors 34 are formed, for example, by filling a plurality of via-holes formed in the fourth insulating layer 14 with conductive paste including copper, a low-melting-point metal (for example, tin), and a resin and heating the conductive paste in a state in which each of the via-holes is closed by a portion of the fourth copper foil.

The ground electrodes 41 to 44 are provided in the laminate substrate 1. As shown in FIGS. 2 and 3, the ground electrodes 41 to 44 are spaced apart from each other in the thickness direction D1 of the laminate substrate 1. In plan view from the thickness direction D1 of the laminate substrate 1, the ground electrodes 41 to 44 overlap each other. The ground electrodes 41 to 44 are adjacent to the signal lines 21 to 24 in the width direction of the signal lines 21 to 24. That “the ground electrodes 41 to 44 are adjacent to the signal lines 21 to 24 in the width direction of the signal lines 21 to 24” means that, in the width direction of the signal lines 21 to 24, the signal lines 21 to 24 and the ground electrodes 41 to 44 are disposed spaced apart from each other without disposition of another conductor between the signal lines 21 to 24 and the ground electrodes 41 to 44. Hereinafter, for convenience of description, the ground electrode 41, the ground electrode 42, the ground electrode 43, and the ground electrode 44 are sometimes referred to as the first ground electrode 41, the second ground electrode 42, the third ground electrode 43, and the fourth ground electrode 44, respectively.

In the present example embodiment, the first ground electrode 41, the second ground electrode 42, the third ground electrode 43, and the fourth ground electrode 44 are adjacent to the first signal line 21, the second signal line 22, the third signal line 23, and the fourth signal line 24 in the width direction of the first signal line 21, the second signal line 22, the third signal line 23, and the fourth signal line 24, respectively.

Each of the ground electrodes 41 to 44 has conductivity. A material of each of the ground electrodes 41 to 44 includes, for example, copper.

A thickness of each of the ground electrodes 41 to 44 is, for example, about 3 μm or more and about 40 μm or less.

The first ground electrode 41 is laminated on the first insulating layer 11. The second ground electrode 42 is laminated on the second insulating layer 12. The third ground electrode 43 is laminated on the third insulating layer 13. The fourth ground electrode 44 is laminated on the fourth insulating layer 14. In the multilayer substrate 100, the first ground electrode 41, the first insulating layer 11, the second insulating layer 12, the second ground electrode 42, the third insulating layer 13, the third ground electrode 43, the fourth insulating layer 14, and the fourth ground electrode 44 are laminated in order of the first ground electrode 41, the first insulating layer 11, the second insulating layer 12, the second ground electrode 42, the third insulating layer 13, the third ground electrode 43, the fourth insulating layer 14, and the fourth ground electrode 44.

Each of the ground electrodes 41 to 44 is arranged in a predetermined pattern. In the present example embodiment, in plan view from the thickness direction D1 of the laminate substrate 1, each of the ground electrodes 41 to 44 has an L-shape, for example. The first ground electrode 41 is formed, for example, by patterning the first copper foil applied to the first insulating layer 11. The second ground electrode 42 is formed, for example, by patterning the second copper foil applied to the second insulating layer 12. The third ground electrode 43 is formed, for example, by patterning the third copper foil applied to the third insulating layer 13. The fourth ground electrode 44 is formed, for example, by patterning the fourth copper foil applied to the fourth insulating layer 14.

In the present example embodiment, the ground electrodes 41 to 44 are electrically connected by a plurality of connection conductors that penetrate one of the insulating layers 11 to 14 in the thickness direction D1 of the laminate substrate 1. The connection conductors include a plurality of fifth connection conductors 51 penetrating the first insulating layer 11, a plurality of sixth connection conductors 52 penetrating the second insulating layer 12, a plurality of seventh connection conductors 53 penetrating the third insulating layer 13, and a plurality of eighth connection conductors 54 penetrating the fourth insulating layer 14. In the present example embodiment, the fifth connection conductors 51 and the sixth connection conductors 52 correspond to each other on a one-to-one basis, and the fifth connection conductor 51 and the sixth connection conductor 52 corresponding to each other overlap in the thickness direction D1 of the laminate substrate 1 and are electrically connected.

In the present example embodiment, the fifth connection conductors 51 overlap the first ground electrode 41 in the thickness direction D1 of the laminate substrate 1. The fifth connection conductors 51 are spaced apart from each other in a length direction of the first ground electrode 41. The length direction of the first ground electrode 41 is a direction along the length direction of the first signal line 21. Further, the sixth connection conductors 52 overlap the second ground electrode 42 in the thickness direction D1 of the laminate substrate 1. The sixth connection conductors 52 are spaced apart from each other in a length direction of the second ground electrode 42. The length direction of the second ground electrode 42 is a direction along the length direction of the second signal line 22. In the present example embodiment, the first ground electrode 41 and the second ground electrode 42 are electrically connected to each other by the fifth connection conductors 51 and the sixth connection conductors 52.

Further, the seventh connection conductors 53 overlap the third ground electrode 43 in the thickness direction D1 of the laminate substrate 1. The seventh connection conductors 53 are spaced apart from each other in a length direction of the third ground electrode 43. The length direction of the third ground electrode 43 is a direction along the length direction of the third signal line 23. In the present example embodiment, the second ground electrode 42 and the third ground electrode 43 are electrically connected to each other by the seventh connection conductors 53.

Further, the eighth connection conductors 54 overlap the fourth ground electrode 44 in the thickness direction D1 of the laminate substrate 1. The eighth connection conductors 54 are spaced apart from each other in a length direction of the fourth ground electrode 44. The length direction of the fourth ground electrode 44 is a direction along the length direction of the fourth signal line 24. In the present example embodiment, the third ground electrode 43 and the fourth ground electrode 44 are electrically connected to each other by the eighth connection conductors 54.

Each of the fifth connection conductors 51, the sixth connection conductors 52, the seventh connection conductors 53, and the eighth connection conductors 54 has conductivity. Each of the fifth connection conductors 51, the sixth connection conductors 52, the seventh connection conductors 53, and the eighth connection conductors 54 includes, for example, copper, a copper-tin alloy, or a resin. The fifth connection conductors 51 are formed, for example, by filling a plurality of via-holes formed in the first insulating layer 11 with conductive paste including copper, a low-melting-point metal (for example, tin), and a resin and heating the conductive paste in a state in which each of the via-holes is closed by a portion of the first copper foil. The sixth connection conductors 52 are formed, for example, by filling a plurality of via-holes formed in the second insulating layer 12 with conductive paste including copper, a low-melting-point metal (for example, tin), and a resin and heating the conductive paste in a state in which each of the via-holes is closed by a portion of the second copper foil. The seventh connection conductors 53 are formed, for example, by filling a plurality of via-holes formed in the third insulating layer 13 with conductive paste including copper, a low-melting-point metal (for example, tin), and a resin and heating the conductive paste in a state in which each of the via-holes is closed by a portion of the third copper foil. The eighth connection conductors 54 are formed, for example, by filling a plurality of via-holes formed in the fourth insulating layer 14 with conductive paste containing copper, a low-melting-point metal (for example, tin), and a resin and heating the conductive paste in a state in which each of the via-holes is closed by a portion of the fourth copper foil.

A transmission line region of the multilayer substrate 100 includes the first transmission line region 101 and the second transmission line region 102. The first transmission line region 101 is a region in which the maximum line width of the signal lines 21 to 24 is smallest in plan view from the thickness direction D1 of the laminate substrate 1, and the second transmission line region 102 is a region in which the maximum line width of the signal lines 21 to 24 is largest. The maximum line width of the signal lines 21 to 24 is the maximum value among the line width W21 of the first signal line 21, the line width W22 of the second signal line 22, the line width W23 of the third signal line 23, and the line width W24 of the fourth signal line 24 in plan view from the thickness direction D1 of the laminate substrate 1. In the multilayer substrate 100 of the present example embodiment, an outer shape width W1 (see FIG. 1) in the width direction of the signal lines 21 to 24 in the first transmission line region 101 is different from an outer shape width W2 (see FIG. 1) in the width direction of the signal lines 21 to 24 in the second transmission line region 102. Specifically, the outer shape width W2 is wider than the outer shape width W1.

In the first transmission line region 101 of the present example embodiment, as shown in FIG. 2, the line width W21 of the first signal line 21, the line width W22 of the second signal line 22, the line width W23 of the third signal line 23, and the line width W24 of the fourth signal line 24 are the same or substantially the same. Accordingly, in the second transmission line region 102, the maximum line width of the signal lines 21 to 24 can be defined by any one of the line widths W21 to W24. In the first transmission line region 101, it is preferable that the line widths W21 to W24 are the same or substantially the same as each other and are wider in terms of increasing the cross-sectional area of the alternating current signal line 2. However, the line widths W21 to W24 may be different from each other. The “cross-sectional area of the alternating current signal line 2” is the total cross-sectional area that is the sum of the cross-sectional areas of the respective signal lines 21 to 24 in any one cross section orthogonal or substantially orthogonal to a length direction of the alternating current signal line 2.

In the first transmission line region 101 of the present example embodiment, as shown in FIG. 2, electrode widths W41 to W44 of the ground electrodes 41 to 44 are the same or substantially the same as each other. However, they may be different from each other.

Further, in the second transmission line region 102 of the present example embodiment, as shown in FIG. 3, the line width W22 of the second signal line 22, the line width W23 of the third signal line 23, and the line width W24 of the fourth signal line 24 are the same or substantially the same, and the line width W21 of the first signal line 21 is the smallest. Accordingly, in the second transmission line region 102, the maximum line width of the signal lines 21 to 24 can be defined by any one of the line widths W22 to W24. In the second transmission line region 102, it is preferable that the line widths W22 to W24 are the same or substantially the same as each other and be wider in terms of increasing the cross-sectional area of the alternating current signal line 2. However, the line widths W22 to W24 may be different from each other.

In the second transmission line region 102 of the present example embodiment, as shown in FIG. 3, the electrode width W41 of one ground electrode 41 among the four ground electrodes 41 to 44 is wider than each of the electrode widths W42 to W44 of the remaining three ground electrodes 42 to 44. Although the electrode widths W42 to W44 of the three ground electrodes 42 to 44 among the four ground electrodes 41 to 44 are the same or substantially the same as each other in the second transmission line region 102 of the present example embodiment, the electrode widths W42 to W44 of the three ground electrodes 42 to 44 may be different from each other.

In the first transmission line region 101 of the present example embodiment, as shown in FIG. 2, the signal lines 21 to 24 do not overlap any of the ground electrodes 41 to 44 in the thickness direction D1 of the laminate substrate 1. In the second transmission line region 102 of the present example embodiment, as shown in FIG. 3, the one ground electrode 41 (first ground electrode 41) among the ground electrodes 41 to 44 overlaps, in the thickness direction D1, the signal lines 22 to 24 other than the signal line 21 adjacent to the ground electrode 41 in the width direction among the signal lines 21 to 24.

In the second transmission line region 102 of the present example embodiment, as shown in FIG. 3, in the signal line 22 adjacent to the ground electrode 41 in the thickness direction D1 of the laminate substrate 1 among the signal lines 21 to 24, a region of at least about half in the width direction overlaps the ground electrode 41 in the thickness direction D1. That the ground electrode 41 and the signal line 22 are adjacent in the thickness direction D1 of the laminate substrate 1 means that the ground electrode 41 and the signal line 22 are spaced apart from each other in the thickness direction D1 and that no other conductor is present between the ground electrode 41 and the signal line 22 in the thickness direction D1. A width H1, in the width direction of the signal line 22, of the region overlapping the ground electrode 41 in the signal line 22 adjacent to the ground electrode 41 in the thickness direction D1 of the laminate substrate 1 is, for example, a value of about one half of the line width W22. The width H1 may be less than the value of about one half of the line width W22. However, it is preferable that the width H1 is greater than or equal to the value of about one half of the line width W22 in terms of improving current distribution in the width direction of each of the signal lines 22 to 24.

The multilayer substrate 100 of the present example embodiment can reduce alternating current resistance of the alternating current signal line 2 compared with a case where the ground electrode is not overlapped with the signal line in the second transmission line region. A mechanism by which the alternating current resistance can be reduced is described below.

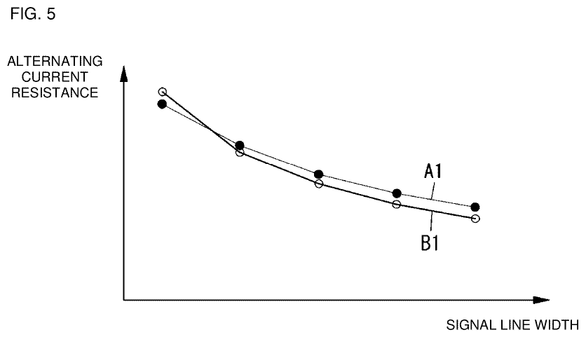

When the maximum line width of the four signal lines 21 to 24 is defined as a signal line width in a transmission line having a layout the same as or similar to that of the first transmission line region 101 and the signal line width is varied, the alternating current resistance decreases as the signal line width increases as indicated by characteristic A1 in FIG. 5. Further, when the ground electrode 41 is overlapped with the three signal lines 22 to 24 in a transmission line having a layout the same as or similar to that of the second transmission line region 102 and a signal line width is varied with the maximum line width of the signal lines 22 to 24 being defined as the signal line width, the alternating current resistance decreases as the signal line width increases as indicated by characteristic B1 in FIG. 5.

From FIG. 5, it can be seen that the alternating current resistance decreases as the signal line width increases in both characteristic A1 and characteristic B1 but characteristic A1 and characteristic B1 intersect each other. Further, from FIG. 5, it can be seen that the characteristic A1 has lower alternating current resistance than the characteristic B1 at a signal line width narrower than the signal line width at the intersection of the characteristic A1 and the characteristic B1. Further, from FIG. 5, it can be seen that the characteristic B1 has lower alternating current resistance than the characteristic A1 at a signal line width wider than the signal line width at the intersection.

Considering the characteristic A1 and the characteristic B1 in FIG. 5, when the signal line width is narrow, the alternating current resistance can be further reduced by providing the layout the same as or similar to that of the first transmission line region 101 to increase the cross-sectional area of the alternating current signal line 2. However, when the layout the same as or similar to that of the first transmission line region 101 is provided, if the signal line width is wide, the current density at a central portion in the width direction becomes lower than that at each of both end portions in the width direction in each of the signal lines 21 to 24, and the reduction effect of the alternating current resistance is reduced. In contrast, when the signal line width is wide, the cross-sectional area of the alternating current signal line 2 can be ensured even when the ground electrode 41 is disposed so as to overlap the signal lines 22 to 24 in the thickness direction D1 of the laminate substrate 1. Thus, by overlapping the ground electrode 41 with the signal lines 22 to 24 in the thickness direction D1 of the laminate substrate 1, a difference between the current density at each of both end portions in the width direction and the current density at the central portion in each of the signal lines 22 to 24 can be reduced, and the alternating current resistance can be further reduced.

In a manufacturing method for the multilayer substrate 100 of the present example embodiment, for example, the first insulating layer 11 on which the first signal line 21 and the first ground electrode 41 are formed, the second insulating layer 12 on which the second signal line 22 and the second ground electrode 42 are formed, the third insulating layer 13 on which the third signal line 23 and the third ground electrode 43 are formed, and the fourth insulating layer 14 on which the fourth signal line 24 and the fourth ground electrode 44 are formed are stacked and disposed over a metal plate (not shown). Then, the stacked layers are pressed from above while being heated, and thus the multilayer substrate 100 is formed.

In the multilayer substrate 100 according to example embodiment 1, the plurality of ground electrodes 41 to 44 are spaced apart from each other in the thickness direction D1 of the laminate substrate 1 and are adjacent to the plurality of signal lines 21 to 24 in the width direction of the signal lines 21 to 24. In the first transmission line region 101, in which the maximum line width of the signal lines 21 to 24 is smallest, the signal lines 21 to 24 do not overlap any of the ground electrodes 41 to 44 in the thickness direction D1 of the laminate substrate 1. In the second transmission line region 102, in which the maximum line width of the signal lines 21 to 24 is largest, the one ground electrode 41 among the ground electrodes 41 to 44 overlaps the signal lines 22 to 24 other than the signal line 21 adjacent to the one ground electrode 41 among the signal lines 21 to 24.

With the above configuration, the alternating current resistance of the multilayer substrate 100 can be reduced. Specifically, in the multilayer substrate 100 according to example embodiment 1, in the first transmission line region 101, in which the maximum line width of the signal lines 21 to 24 is smallest, the signal lines 21 to 24 do not overlap any of the ground electrodes 41 to 44 in the thickness direction D1 of the laminate substrate 1. Thus, the cross-sectional area of the alternating current signal line 2 can be increased, and the alternating current resistance can be reduced. Further, in the multilayer substrate 100 according to example embodiment 1, in the second transmission line region 102, in which the maximum line width of the signal lines 21 to 24 is largest, the one ground electrode 41 among the ground electrodes 41 to 44 overlaps the signal lines 22 to 24 other than the signal line 21 adjacent to the one ground electrode 41 among the signal lines 21 to 24. Thus, unevenness of the current density in the width direction of the signal lines 21 to 24 can be reduced or prevented, and the alternating current resistance can be further reduced.

Further, in the second transmission line region 102 of the multilayer substrate 100 according to example embodiment 1, in the signal line 22 adjacent to the one ground electrode 41 in the thickness direction D1 of the laminate substrate 1 among the signal lines 21 to 24, the region of at least about half in the width direction overlaps the one ground electrode 41 in the thickness direction D1.

With the above configuration, compared with a case where a region that is less than about half in the width direction in the signal line 22 overlaps the one ground electrode 41 in the thickness direction D1 of the laminate substrate 1, current distribution in the width direction of the signal lines 22 to 24 can be improved and unevenness of the current density can be further reduced or prevented. Thus, the alternating current resistance can be further reduced.

Further, in the multilayer substrate 100 according to example embodiment 1, the outer shape width W2 in the width direction of the signal lines 21 to 24 in the second transmission line region 102 is wider than the outer shape width W1 in the width direction of the signal lines 21 to 24 in the first transmission line region 101.

With the above configuration, it is possible to further reduce the alternating current resistance in each of the first transmission line region 101 and the second transmission line region 102 regarding the alternating current signal line 2.

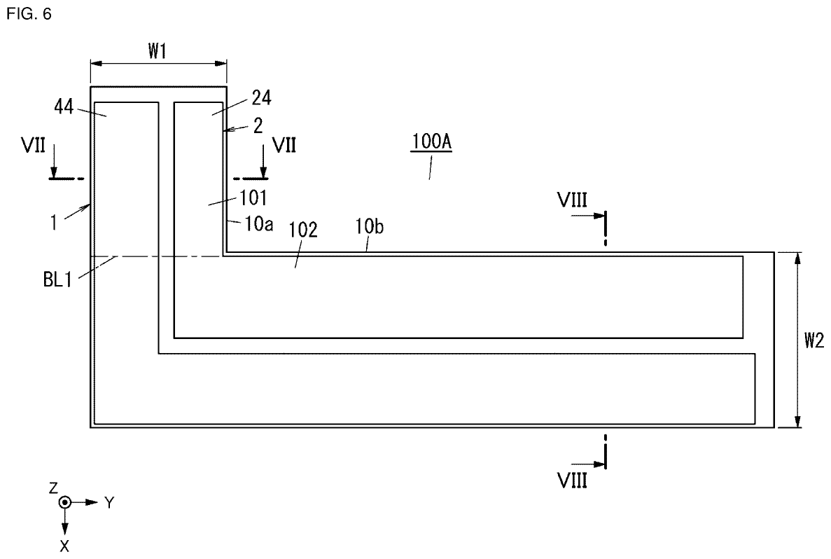

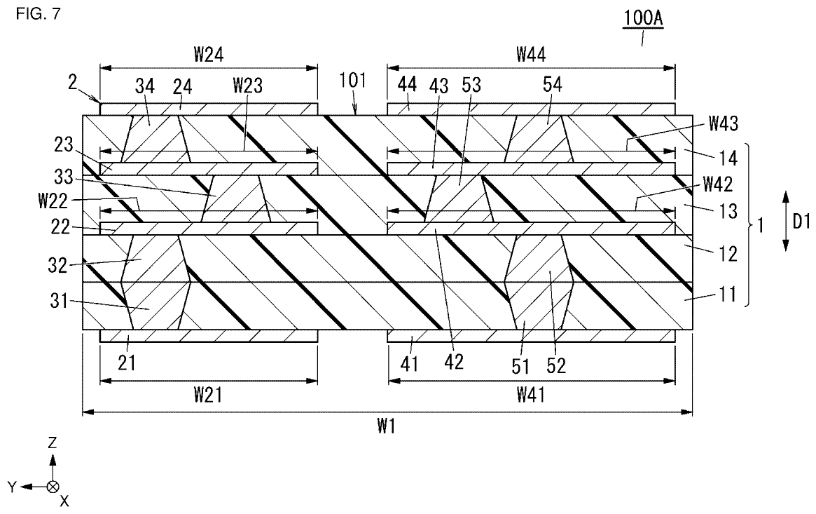

A multilayer substrate 100A according to example embodiment 2 of the present invention is described with reference to FIGS. 6 to 8. For the multilayer substrate 100A according to example embodiment 2, components the same as or similar to those of the multilayer substrate 100 according to example embodiment 1 (see FIGS. 1 to 4) are denoted by the same reference numerals, and description thereof is omitted. In each of FIGS. 6 to 8, similarly to FIGS. 1 to 4, a Cartesian coordinate system having three axes of an X-axis, a Y-axis, and a Z-axis orthogonal or substantially orthogonal to each other is defined, and an axis along the thickness direction D1 (see FIG. 7) of the laminate substrate 1 is indicated as the Z-axis.

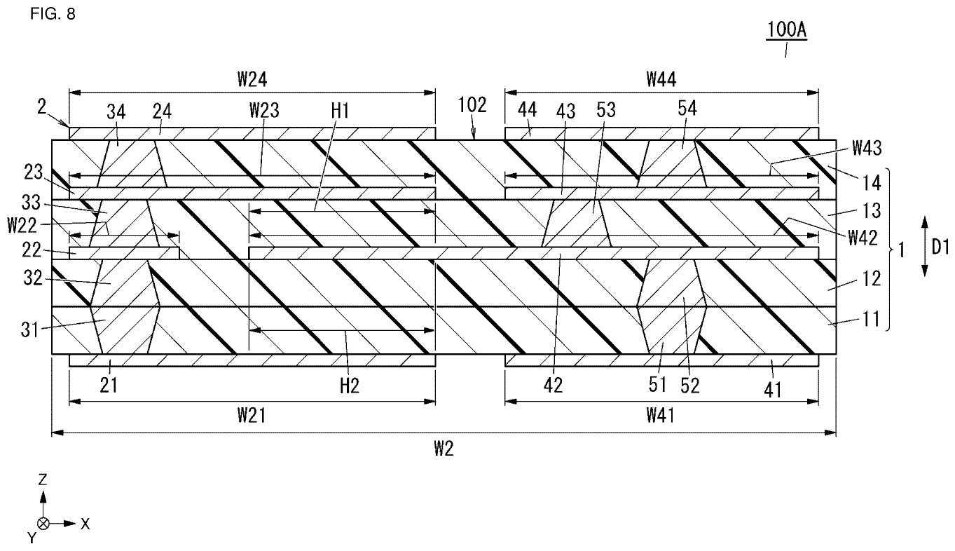

The multilayer substrate 100A according to example embodiment 2 is different from the multilayer substrate 100 according to example embodiment 1 in that, as shown in FIG. 8, not the first ground electrode 41 but the second ground electrode 42 among the four ground electrodes 41 to 44 overlaps the signal lines 21, 23, and 24 in the thickness direction D1 of the laminate substrate 1.

Further, in the second transmission line region 102 of the present example embodiment, as shown in FIG. 8, the line width W21 of the first signal line 21, the line width W23 of the third signal line 23, and the line width W24 of the fourth signal line 24 are the same, and the line width W22 of the second signal line 22 is the smallest. Accordingly, in the second transmission line region 102, the maximum line width of the signal lines 21 to 24 can be defined by any one of the line widths W21, W23, and W24. In the second transmission line region 102, it is preferable that the line widths W21, W23, and W24 are the same or substantially the same as each other and are wider in terms of increasing the cross-sectional area of the alternating current signal line 2. However, the line widths W21, W23, and W24 may be different from each other.

In the second transmission line region 102 of the present example embodiment, as shown in FIG. 8, the electrode width W42 of one ground electrode 42 among the four ground electrodes 41 to 44 is wider than each of the electrode widths W41, W43, and W44 of the remaining three ground electrodes 41, 43, and 44. Although the electrode widths W41, W43, and W44 of the three ground electrodes 41, 43, and 44 among the four ground electrodes 41 to 44 are the same or substantially the same as each other in the second transmission line region 102 of the present example embodiment, the electrode widths W41, W43, and W44 of the three ground electrodes 41, 43, and 44 may be different from each other.

In the first transmission line region 101 of the present example embodiment, as shown in FIG. 7, the signal lines 21 to 24 do not overlap any of the ground electrodes 41 to 44 in the thickness direction D1 of the laminate substrate 1. In the second transmission line region 102 of the present example embodiment, as shown in FIG. 8, the one ground electrode 42 (second ground electrode 42) among the ground electrodes 41 to 44 overlaps, in the thickness direction D1, the signal lines 21, 23, and 24 other than the signal line 22 adjacent to the ground electrode 42 in the width direction among the signal lines 21 to 24.

In the second transmission line region 102 of the present example embodiment, in the signal line 21 adjacent to the ground electrode 42 in the thickness direction D1 among the signal lines 21 to 24, a region of at least about half in the width direction overlaps the ground electrode 42 in the thickness direction D1. The width H1, in the width direction of the signal line 23, of a region overlapping the ground electrode 42 in the signal line 23 adjacent to the ground electrode 42 in the thickness direction D1 is, for example, a value of about one half of the line width W23. The width H1 may be less than the value of about one half of the line width W23. However, it is preferable that the width H1 is greater than or equal to the value of about one half of the line width W23 in terms of improving current distribution in the width direction of each of the signal lines 21, 23, and 24. A width H2, in the width direction of the signal line 21, of the region overlapping the ground electrode 42 in the signal line 21 adjacent to the ground electrode 42 in the thickness direction D1 is, for example, a value of one half of the line width W21. The width H2 may be less than the value of about one half of the line width W21. However, it is preferable that the width H2 is greater than or equal to the value of about one half of the line width W21 in terms of improving the current distribution in the width direction of each of the signal lines 21, 23, and 24.

The multilayer substrate 100A according to example embodiment 2 can reduce the alternating current resistance of the multilayer substrate 100A similarly to the multilayer substrate 100 according to example embodiment 1. Specifically, in the multilayer substrate 100A according to example embodiment 2, in the first transmission line region 101, the signal lines 21 to 24 do not overlap any of the ground electrodes 41 to 44 in the thickness direction D1 of the laminate substrate 1. Thus, the cross-sectional area of the alternating current signal line 2 can be increased, and the alternating current resistance can be reduced. Further, in the multilayer substrate 100A according to example embodiment 2, in the second transmission line region 102, the one ground electrode 42 among the ground electrodes 41 to 44 overlaps the signal lines 21, 23, and 24 other than the signal line 22 adjacent to the one ground electrode 42 among the signal lines 21 to 24. Thus, unevenness of the current density in the width direction of the signal lines 21 to 24 can be reduced or presented, and the alternating current resistance can be further reduced.

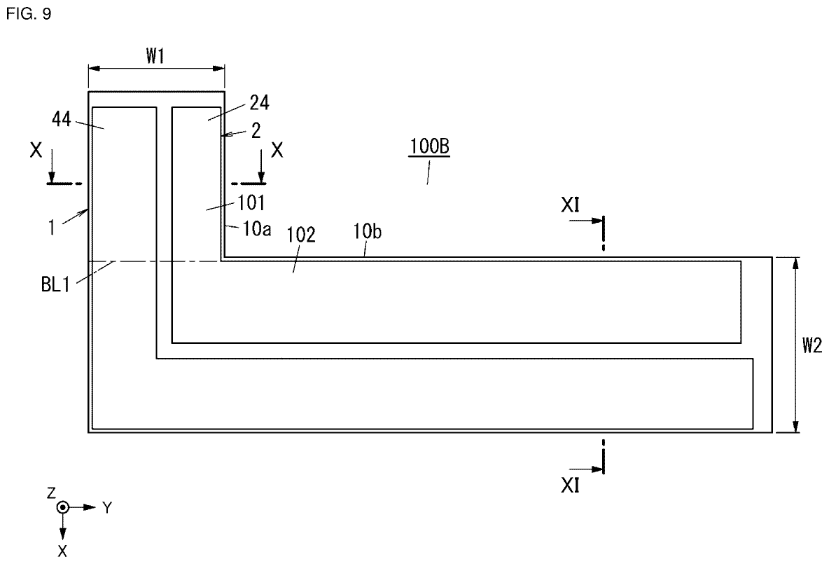

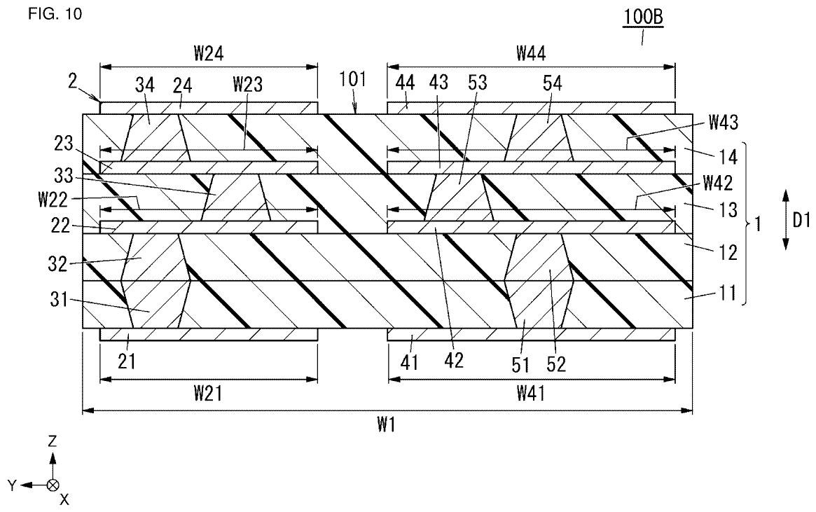

A multilayer substrate 100B according to example embodiment 3 of the present invention is described with reference to FIGS. 9 to 11. For the multilayer substrate 100B according to example embodiment 3, components the same as or similar to those of the multilayer substrate 100 according to example embodiment 1 (see FIGS. 1 to 4) are denoted by the same reference numerals, and description thereof is omitted. In FIGS. 9 to 11, similarly to FIGS. 1 to 4, a Cartesian coordinate system having three axes of an X-axis, a Y-axis, and a Z-axis orthogonal or substantially orthogonal to each other is defined, and an axis along the thickness direction D1 (see FIG. 10) of the laminate substrate 1 is indicated as the Z-axis.

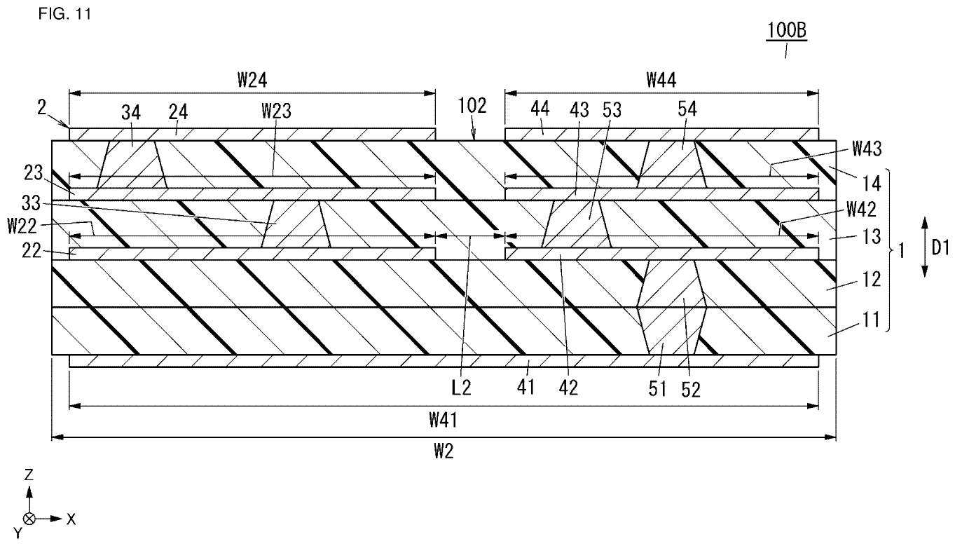

In the second transmission line region 102 of the multilayer substrate 100B according to example embodiment 3, as shown in FIG. 11, the entire or substantially the entire region of the signal line 22 adjacent to the ground electrode 41 in the thickness direction D1 of the laminate substrate 1 overlaps the ground electrode 41 in the thickness direction D1. The electrode width W41 of the ground electrode 41 in the width direction of the signal line 22 is the total length of the line width W22 of the signal line 22, the electrode width W42 of the ground electrode 42, and a distance L2 between the signal line 22 and the ground electrode 42. The ground electrode 41 may be shorter than the above total length as long as it has such a length as to overlap the entire or substantially the entire region of the signal line 22 and the fifth connection conductor 51.

The multilayer substrate 100B according to example embodiment 3 can reduce the alternating current resistance of the multilayer substrate 100B similarly to the multilayer substrate 100 according to example embodiment 1.

Further, in the second transmission line region 102 of the multilayer substrate 100B according to example embodiment 3, in the signal line 22 adjacent to one ground electrode 41 in the thickness direction D1 among the signal lines 21 to 24, the entire or substantially the entire region in the width direction overlaps the one ground electrode 41 in the thickness direction D1.

With the above configuration, noise resistance can be improved.

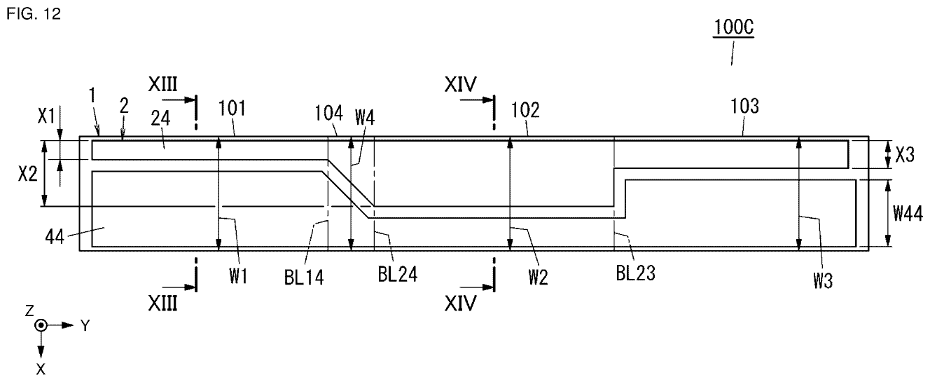

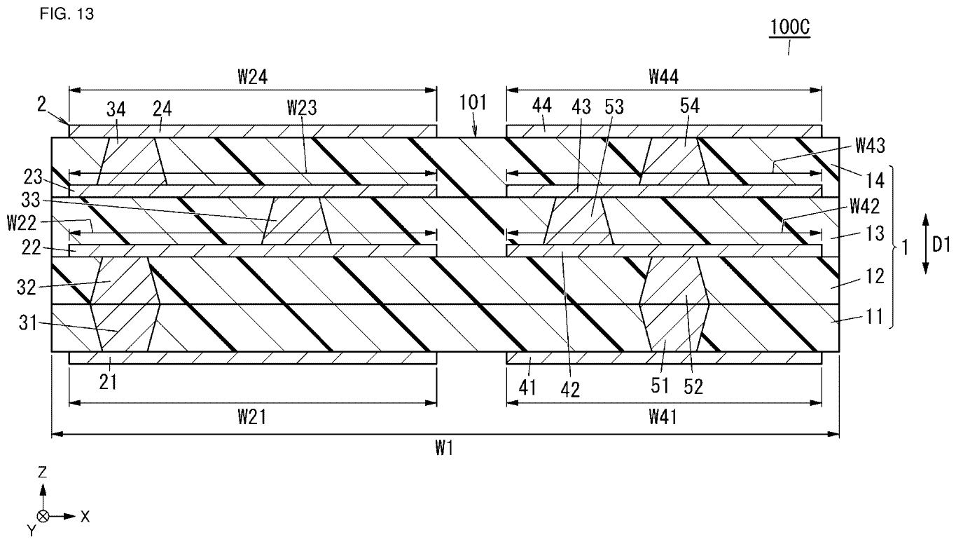

A multilayer substrate 100C according to example embodiment 4 of the present invention is described with reference to FIGS. 12 to 14. For the multilayer substrate 100C according to example embodiment 4, components the same as or similar to those of the multilayer substrate 100 according to example embodiment 1 (see FIGS. 1 to 4) are denoted by the same reference numerals, and description thereof is omitted. In each of FIGS. 12 to 14, similarly to FIGS. 1 to 4, a Cartesian coordinate system having three axes of an X-axis, a Y-axis, and a Z-axis orthogonal or substantially orthogonal to each other is defined, and an axis along the thickness direction D1 (see FIG. 13) of the laminate substrate 1 is indicated as the Z-axis.

In the multilayer substrate 100C according to example embodiment 4, as shown in FIG. 12, in plan view from the thickness direction D1 of the laminate substrate 1, the laminate substrate 1 has an elongated shape in which a length in a direction along the Y-axis is longer than a length in a direction along the X-axis.

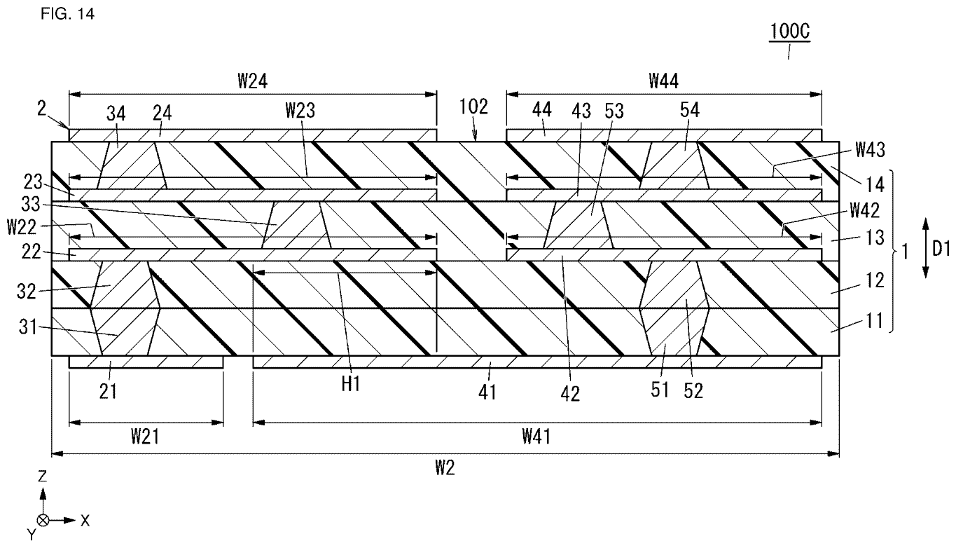

In the multilayer substrate 100C, the outer shape width W1 in the width direction of the signal lines 21 to 24 in the first transmission line region 101 (see FIG. 13) is the same or substantially the same as the outer shape width W2 in the width direction of the signal lines 21 to 24 in the second transmission line region 102 (see FIG. 14).

In the present example embodiment, a transmission line region of the multilayer substrate 100C includes the first transmission line region 101, the second transmission line region 102, and a third transmission line region 103 located on a side opposite to the first transmission line region 101 side with respect to the second transmission line region 102. Further, the transmission line region of the multilayer substrate 100C further includes a fourth transmission line region 104 located between the first transmission line region 101 and the second transmission line region 102. Accordingly, in the multilayer substrate 100C, the first transmission line region 101, the fourth transmission line region 104, the second transmission line region 102, and the third transmission line region 103 are arranged in order of the first transmission line region 101, the fourth transmission line region 104, the second transmission line region 102, and the third transmission line region 103. In the multilayer substrate 100C, the outer shape width W1 of the first transmission line region 101, an outer shape width W4 of the fourth transmission line region 104, the outer shape width W2 of the second transmission line region 102, and an outer shape width W3 of the third transmission line region 103 are the same or substantially the same.

In FIG. 12, a boundary BL14 between the first transmission line region 101 and the fourth transmission line region 104 is shown by a dash-dot line. In FIG. 12, a boundary BL24 between the fourth transmission line region 104 and the second transmission line region 102 is shown by a dash-dot line. In FIG. 12, a boundary BL23 between the second transmission line region 102 and the third transmission line region 103 is shown by a dash-dot line. The respective boundaries BL14, BL23, and BL24 are virtual boundaries shown for description.

In FIG. 12, the maximum line width in the first transmission line region 101 (in the example of FIG. 13, line widths W21 to W24 of the signal lines 21 to 24) is shown as X1. Further, in FIG. 12, the maximum line width in the second transmission line region 102 (in the example of FIG. 14, line widths W22 to W24 of the signal lines 22 to 24) is shown as X2. In addition, in FIG. 12, the maximum line width in the third transmission line region 103 is shown as X3. In the multilayer substrate 100C, X1 in the first transmission line region 101 is constant in a length direction of the first transmission line region 101, and X2 in the second transmission line region 102 is constant in a length direction of the second transmission line region 102, and X3 in the third transmission line region 103 is constant in a length direction of the third transmission line region 103. Further, for example, in the multilayer substrate 100C, X1<X3<X2. Further, in the multilayer substrate 100C, the maximum line width in the fourth transmission line region 104 increases as the position becomes farther from the first transmission line region 101 and closer to the second transmission line region 102.

In the present example embodiment, the electrode width W44 of the ground electrode 44 in the first transmission line region 101 is wider than the electrode width W44 of the ground electrode 44 in the third transmission line region 103, and the electrode width W44 of the ground electrode 44 in the third transmission line region 103 is wider than the electrode width W44 of the ground electrode 44 in the second transmission line region 102.

In the third transmission line region 103 of the present example embodiment, for example, a condition of X3≤(X1+X2)/2 is satisfied. Further, similarly to the first transmission line region 101 (see FIG. 13), the signal lines 21 to 24 do not overlap any of the ground electrodes 41 to 44 in the thickness direction D1 of the laminate substrate 1.

In the third transmission line region 103, for example, when a condition of X3>(X1+X2)/2 is satisfied, similarly to the second transmission line region 102, one ground electrode 41 among the ground electrodes 41 to 44 overlaps the signal lines 22 to 24 other than the signal line 21 adjacent to the one ground electrode 41 among the signal lines 21 to 24.

In the present example embodiment, the maximum line width in the fourth transmission line region 104 is wider than (X1+X2)/2, and, similarly to the second transmission line region 102, one ground electrode 41 among the ground electrodes 41 to 44 overlaps the signal lines 22 to 24 other than the signal line 21 adjacent to the one ground electrode 41 among the signal lines 21 to 24.

The multilayer substrate 100C according to example embodiment 4 can reduce the alternating current resistance similarly to the multilayer substrate 100 according to example embodiment 1.

Further, in the multilayer substrate 100C according to example embodiment 4, when the maximum line width in the first transmission line region 101 is defined as X1 and the maximum line width in the second transmission line region 102 is defined as X2, in the third transmission line region 103, in which the maximum line width of the signal lines 21 to 24 is greater than X1 and less than or equal to (X1+X2)/2, the signal lines 21 to 24 do not overlap any of the ground electrodes 41 to 44 in the thickness direction D1.

With the above configuration, it is possible to reduce the alternating current resistance when the alternating current signal line 2 is extends across the first transmission line region 101, the second transmission line region 102, and the third transmission line region 103.

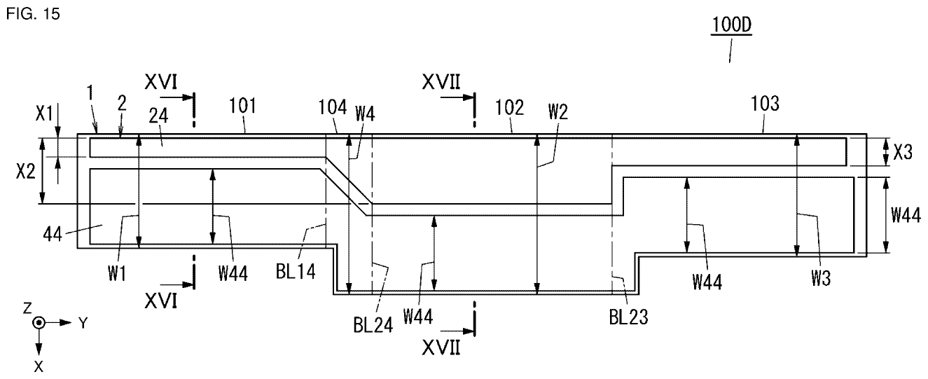

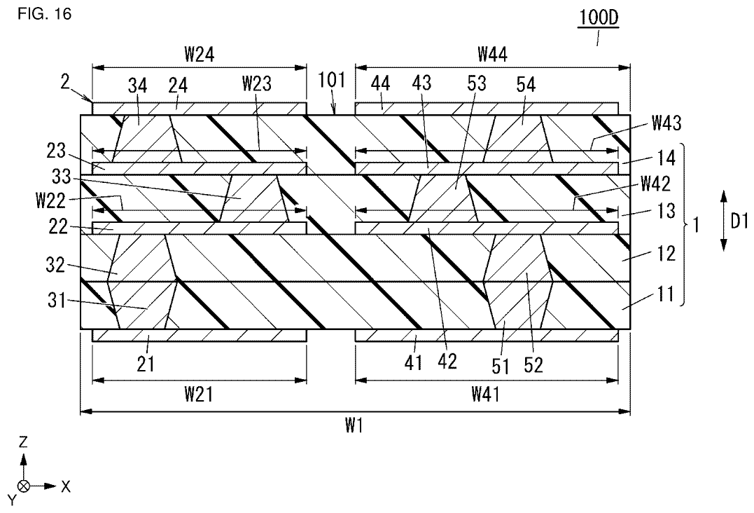

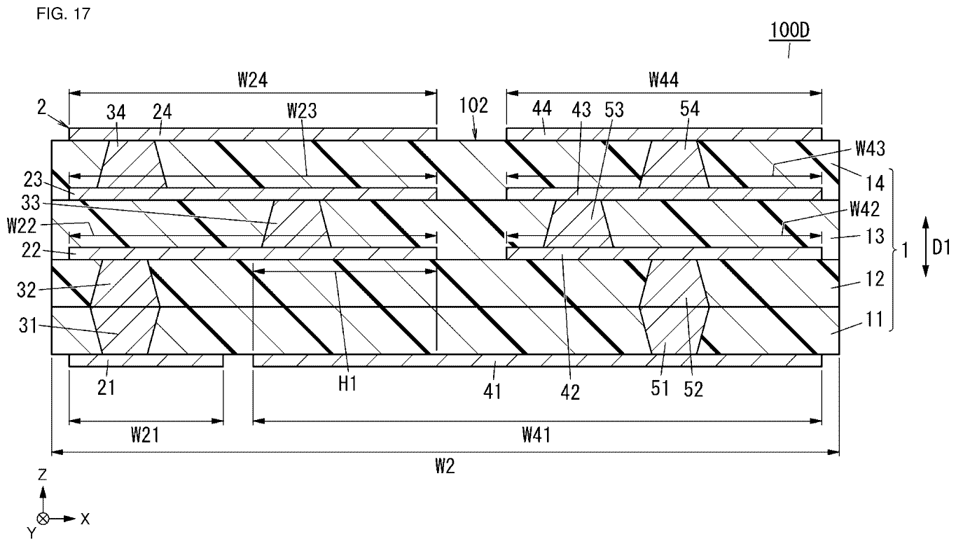

A multilayer substrate 100D according to example embodiment 5 of the present invention is described with reference to FIGS. 15 to 17. For the multilayer substrate 100D according to example embodiment 5, components the same as or similar to those of the multilayer substrate 100C according to example embodiment 4 (see FIGS. 12 to 14) are denoted by the same reference numerals, and description thereof is omitted. In each of FIGS. 15 to 17, similarly to FIGS. 12 to 14, a Cartesian coordinate system having three axes of an X-axis, a Y-axis, and a Z-axis orthogonal or substantially orthogonal to each other is defined, and an axis along the thickness direction D1 (see FIG. 16) of the laminate substrate 1 is indicated as the Z-axis.

In the multilayer substrate 100D according to example embodiment 5, as shown in FIG. 15, the outer shape width W2 of the second transmission line region 102 is wider than the outer shape width W3 of the third transmission line region 103, and the outer shape width W3 of the third transmission line region 103 is wider than the outer shape width W1 of the first transmission line region 101.

In the present example embodiment, the electrode width W44 of the ground electrode 44 in the first transmission line region 101, the electrode width W44 of the ground electrode 44 in the third transmission line region 103, and the electrode width W44 of the ground electrode 44 in the second transmission line region 102 are the same or substantially the same.

The multilayer substrate 100D according to example embodiment 5 can reduce the alternating current resistance similarly to the multilayer substrate 100C according to example embodiment 4.

Further, compared with the multilayer substrate 100C according to example embodiment 4, the multilayer substrate 100D according to example embodiment 5 can increase the areas of the ground electrodes 41 to 44 and further stabilize the potentials of the ground electrodes 41 to 44.

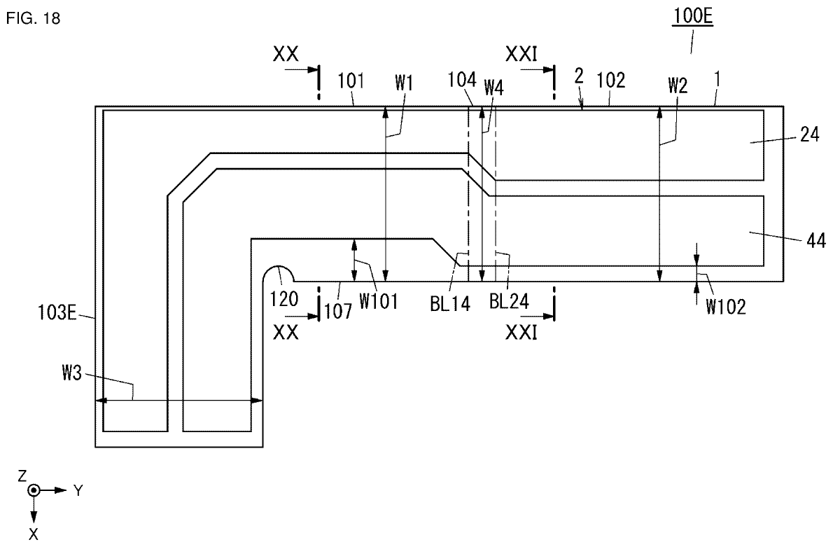

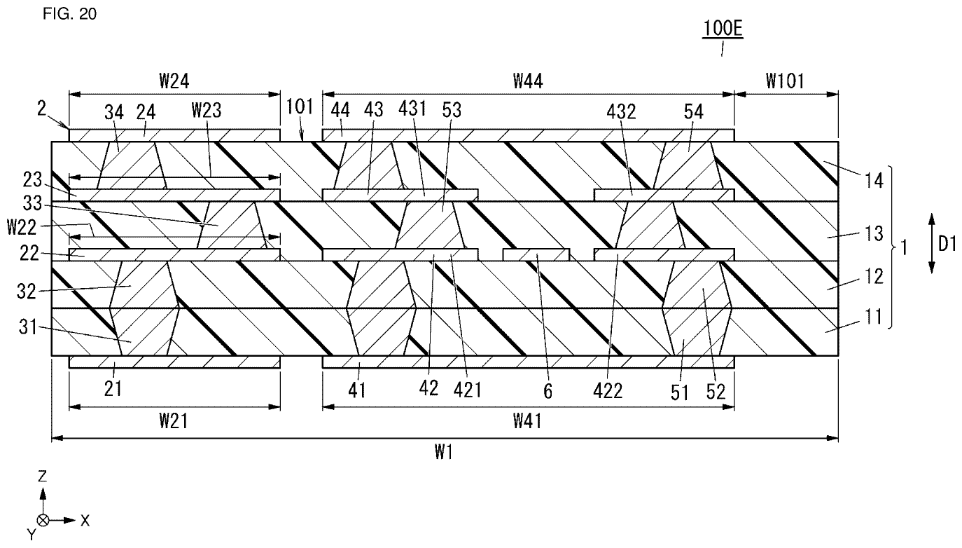

A multilayer substrate 100E according to example embodiment 6 of the present invention is described with reference to FIGS. 18 to 21. For the multilayer substrate 100E according to example embodiment 6, components the same as or similar to those of the multilayer substrate 100C according to example embodiment 4 (see FIGS. 12 to 14) are denoted by the same reference numerals, and description thereof is omitted. In each of FIGS. 18 to 21, similarly to FIGS. 12 to 14, a Cartesian coordinate system having three axes of an X-axis, a Y-axis, and a Z-axis orthogonal or substantially orthogonal to each other is defined, and an axis along the thickness direction D1 (see FIG. 20) of the laminate substrate 1 is indicated as the Z-axis.

In the multilayer substrate 100E according to example embodiment 6, as shown in FIG. 18, the outer shape width W1 of the first transmission line region 101, the outer shape width W2 of the second transmission line region 102, the outer shape width W3 of a third transmission line region 103E, and the outer shape width W4 of the fourth transmission line region 104 are the same or substantially the same.

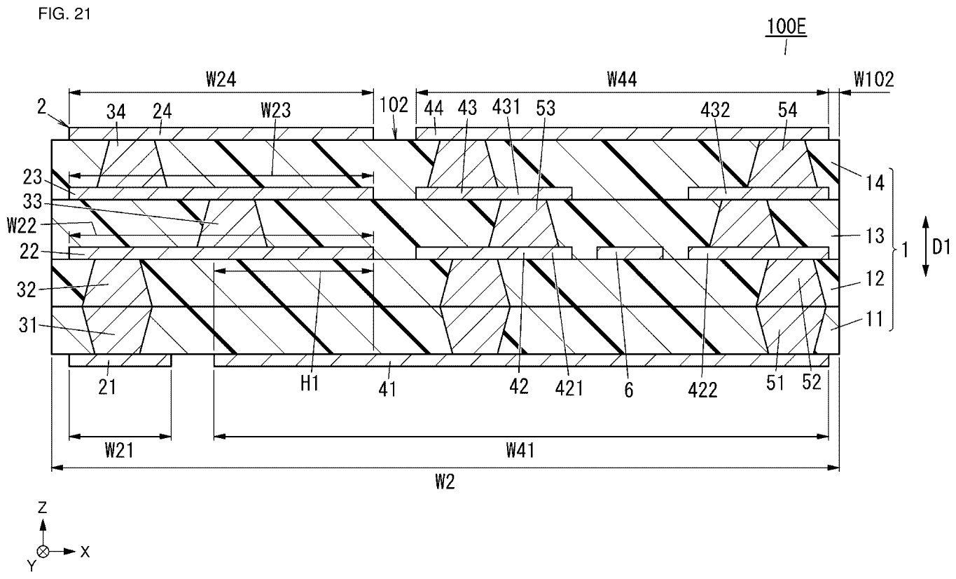

In the multilayer substrate 100E according to example embodiment 6, the electrode width W44 of the ground electrode 44 in the first transmission line region 101 (see FIG. 20) is the same or substantially the same as the electrode width W44 of the ground electrode 44 in the second transmission line region 102 (see FIG. 21). Further, in the multilayer substrate 100E, a width W101 of a portion adjacent to the ground electrodes 41 to 44 on a side opposite to the signal lines 21 to 24 side in the first transmission line region 101 is wider than a width W102 of a portion adjacent to the ground electrodes 41 to 44 on the side opposite to the signal lines 21 to 24 side in the second transmission line region 102.

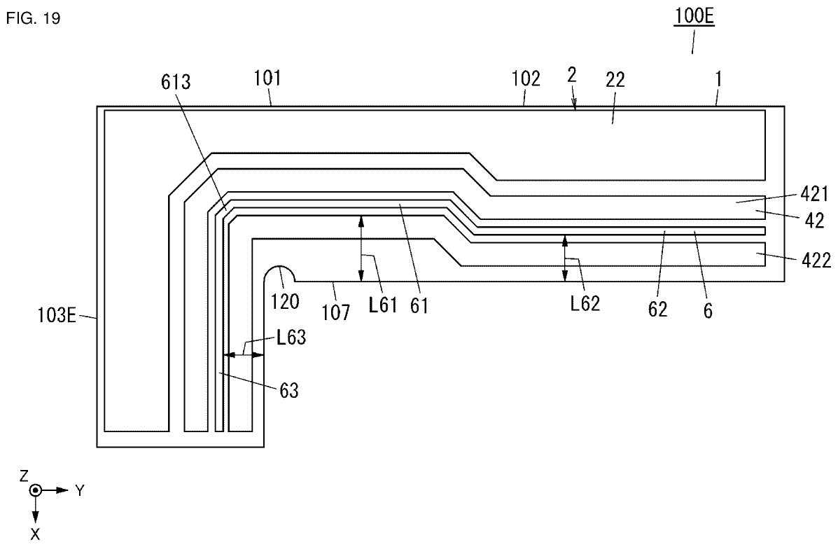

Further, as shown in FIGS. 19 to 21, the multilayer substrate 100E according to example embodiment 6 further includes an RF signal line 6. The RF signal line 6 is provided in the laminate substrate 1. The RF signal line 6 extends across the first transmission line region 101, the second transmission line region 102, and the third transmission line region 103E. The frequency of a high frequency signal transmitted through the RF signal line 6 is a frequency (for example, 2.45 GHz) higher than the frequency of a signal transmitted through the alternating current signal line 2 (for example, 13.56 MHz). The RF signal line 6 is designed, for example, such that the impedance of the RF signal line 6 is about 50 Ω. As shown in FIGS. 20 and 21, the RF signal line 6 is located between the first ground electrode 41 and the fourth ground electrode 44 in the thickness direction D1 of the laminate substrate 1. Accordingly, in the multilayer substrate 100E, a strip line is provided with the laminate substrate 1, the RF signal line 6, the first ground electrode 41, and the fourth ground electrode 44. In the present example embodiment, the second ground electrode 42 is divided into two split ground electrodes 421 and 422 in the width direction of the signal line 22, and the third ground electrode 43 is divided into two split ground electrodes 431 and 432 in the width direction of the signal line 23. In the present example embodiment, the RF signal line 6 is disposed between the two split ground electrodes 421 and 422.

Further, in the multilayer substrate 100E, the length direction of the first transmission line region 101 and the length direction of the second transmission line region 102 are directions along the Y-axis, and a length direction of the third transmission line region 103E is a direction along the X-axis. Accordingly, in the multilayer substrate 100E, the length direction of the second transmission line region 102 and the length direction of the third transmission line region 103E are orthogonal or substantially orthogonal to each other.

The signal lines 21 to 24 extend across the first transmission line region 101, the second transmission line region 102, and the third transmission line region 103E. The width direction of the signal lines 21 to 24 in the first transmission line region 101 is orthogonal or substantially orthogonal to the width direction of the signal lines 21 to 24 in the third transmission line region 103E. The RF signal line 6 includes a first portion 61 provided in the first transmission line region 101, a second portion 62 provided in the second transmission line region 102, and a third portion 63 provided in the third transmission line region 103E.

In the multilayer substrate 100E, in plan view from the thickness direction D1 of the laminate substrate 1, a concave portion 120 is provided in an outer edge 107 of the laminate substrate 1 at an end portion of the first transmission line region 101 on the third transmission line region 103E side in a width direction (direction along the X-axis). The concave portion 120 facilitates bending of the multilayer substrate 100E in the first transmission line region 101. As shown in FIG. 19, when viewed from the thickness direction D1 of the laminate substrate 1, a first shortest distance L61 between the first portion 61 of the RF signal line 6 and the outer edge 107 of the laminate substrate 1 is longer than a second shortest distance L62 between the second portion 62 of the RF signal line 6 and the outer edge 107 of the laminate substrate 1 and is longer than a third shortest distance L63 between the third portion 63 of the RF signal line 6 and the outer edge 107 of the laminate substrate 1. The first shortest distance L61 is set to a value larger than a depth of the concave portion 120 so that the first portion 61 of the RF signal line 6 may be arranged so as not to overlap the concave portion 120 in a direction in which the first transmission line region 101 and the second transmission line region 102 are arranged (direction parallel to the Y-axis). When viewed from the thickness direction D1 of the laminate substrate 1, a connecting portion 613 between the first portion 61 and the third portion 63 in the RF signal line 6 has a shape curved more gently than the outer edge 107 of the laminate substrate 1. That is, the connecting portion 613 of the RF signal line 6 is curved more gently than in a case where the RF signal line 6 is bent by about 90 degrees so as to bypass the concave portion 120.

The multilayer substrate 100E according to example embodiment 6 can reduce the alternating current resistance similarly to the multilayer substrate 100C according to example embodiment 4.

Further, the multilayer substrate 100E according to example embodiment 6 further includes the RF signal line 6.

With the above configuration, it is also possible to use the multilayer substrate 100E for transmission of a high frequency signal by the RF signal line 6 in addition to transmission of a signal by the alternating current signal line 2.

Further, in the multilayer substrate 100E according to example embodiment 6, when viewed from the thickness direction D1 of the laminate substrate 1, the connecting portion 613 of the RF signal line 6 between the first portion 61 provided in the first transmission line region 101 and the third portion 63 provided in the third transmission line region 103E has a shape curved more gently than the outer edge 107 of the laminate substrate 1.

With the above configuration, impedance deviation of the RF signal line 6 can be reduced or prevented.

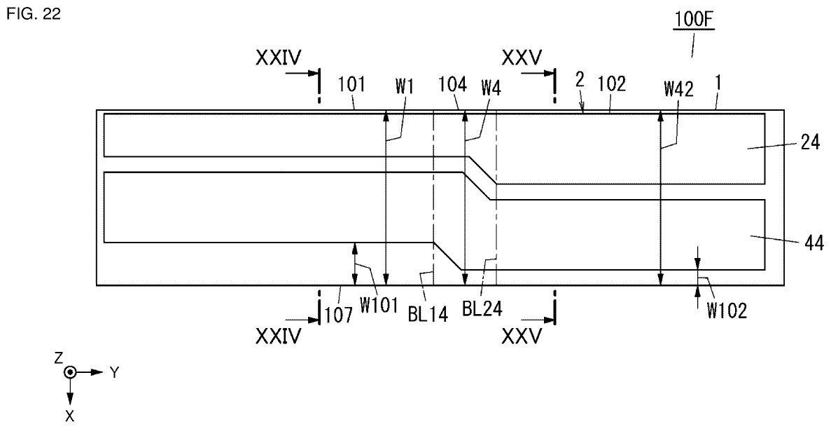

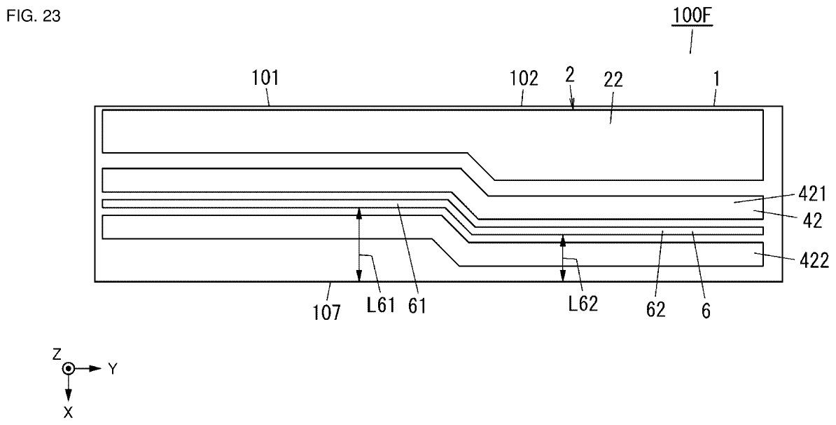

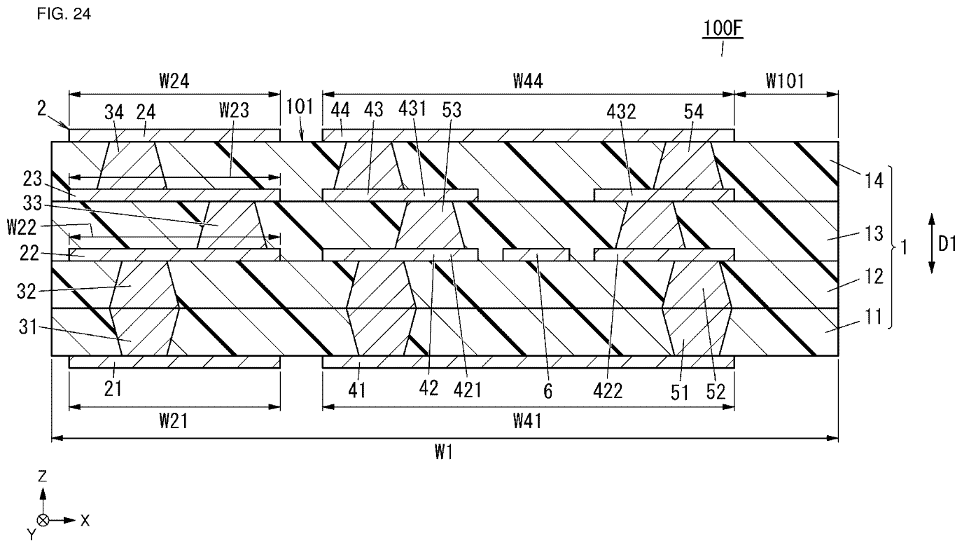

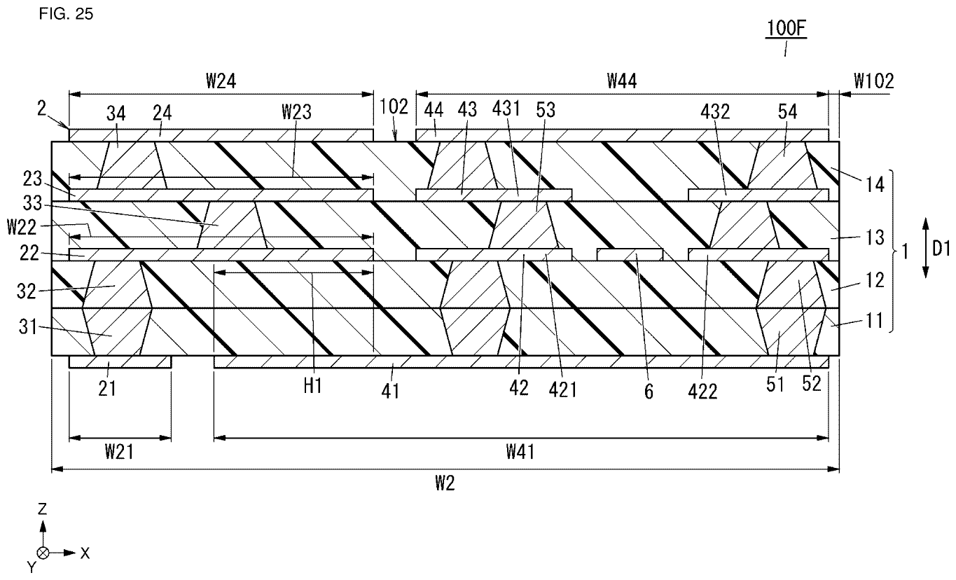

A multilayer substrate 100F according to example embodiment 7 of the present invention is described with reference to FIGS. 22 to 25. For the multilayer substrate 100F according to example embodiment 7, components the same as or similar to those of the multilayer substrate 100E according to example embodiment 6 (see FIGS. 18 to 21) are denoted by the same reference numerals, and description thereof is omitted. In each of FIGS. 22 to 25, similarly to FIGS. 18 to 21, a Cartesian coordinate system having three axes of an X-axis, a Y-axis, and a Z-axis orthogonal or substantially orthogonal to each other is defined, and an axis along the thickness direction D1 (see FIG. 24) of the laminate substrate 1 is indicated as the Z-axis.

The multilayer substrate 100F according to example embodiment 7 is different from the multilayer substrate 100E according to example embodiment 6 in that the multilayer substrate 100F does not include the third transmission line region 103E of the multilayer substrate 100E.

In the multilayer substrate 100F, a width of the laminate substrate 1 in the width direction of the signal lines 21 to 24 is constant. In the multilayer substrate 100F, the area of the conductor in a cross section of the first transmission line region 101 orthogonal or substantially orthogonal to a direction in which the first transmission line region 101 and the second transmission line region 102 are arranged is smaller than the area of the conductor in a cross section of the second transmission line region 102 orthogonal or substantially orthogonal to the direction in which the first transmission line region 101 and the second transmission line region 102 are arranged.

The multilayer substrate 100F according to example embodiment 7 can reduce the alternating current resistance similarly to the multilayer substrate 100E according to example embodiment 6.

Further, in the multilayer substrate 100F according to example embodiment 7, the total cross-sectional area of the signal lines 21 to 24 and the ground electrodes 41 to 44 in a cross section of the first transmission line region 101 orthogonal or substantially orthogonal to the length direction of the signal lines 21 to 24 is smaller than the total cross-sectional area of the signal lines 21 to 24 and the ground electrodes 41 to 44 in a cross section of the second transmission line region 102 orthogonal or substantially orthogonal to the length direction of the signal lines 21 to 24.

With the above configuration, the multilayer substrate 100F is easier to bend in the first transmission line region 101 than in the second transmission line region 102.

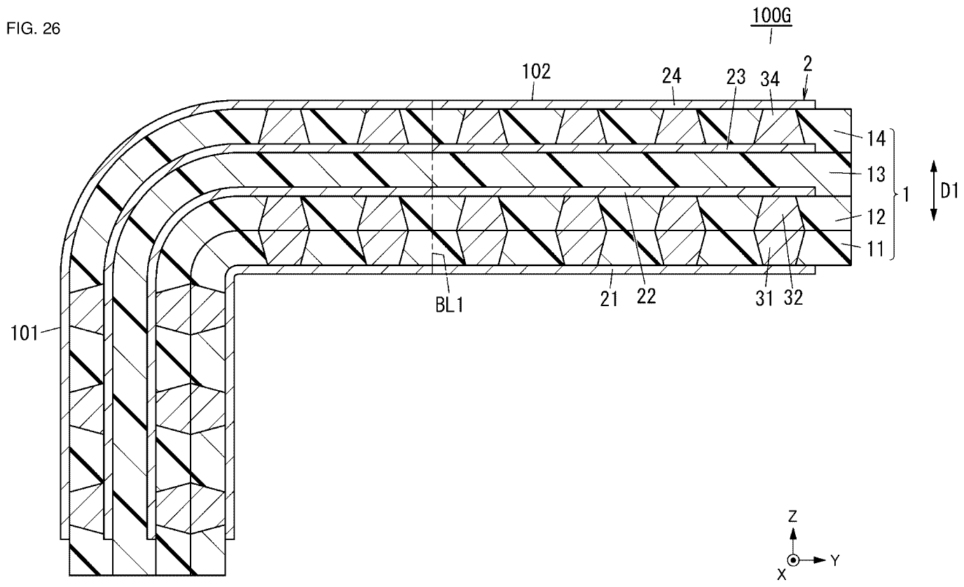

A multilayer substrate 100G according to example embodiment 8 of the present invention is described with reference to FIG. 26. For the multilayer substrate 100G according to example embodiment 8, components the same as or similar to those of the multilayer substrate 100F according to example embodiment 7 (see FIGS. 22 to 25) are denoted by the same reference numerals, and description thereof is omitted. In FIG. 26, similarly to FIGS. 22 to 25, a Cartesian coordinate system having three axes of an X-axis, a Y-axis, and a Z-axis orthogonal or substantially orthogonal to each other is defined and indicated.

The multilayer substrate 100G according to example embodiment 8 is different from the multilayer substrate 100F according to example embodiment 7 in that the multilayer substrate 100G is bent in the first transmission line region 101 as shown in FIG. 26.

The multilayer substrate 100G has been subjected to bending processing by plastically deforming a thermoplastic resin in the first transmission line region 101, and the multilayer substrate 100G itself maintains its shape.

The multilayer substrate 100G according to example embodiment 8 can reduce the alternating current resistance similarly to the multilayer substrate 100F according to example embodiment 7.

Further, because the multilayer substrate 100G according to example embodiment 8 is bent in the first transmission line region 101, for example, disposition of the multilayer substrate 100G in a housing of electronic equipment is facilitated when a storage space for the multilayer substrate 100G in the housing of the electronic equipment is a curved space.

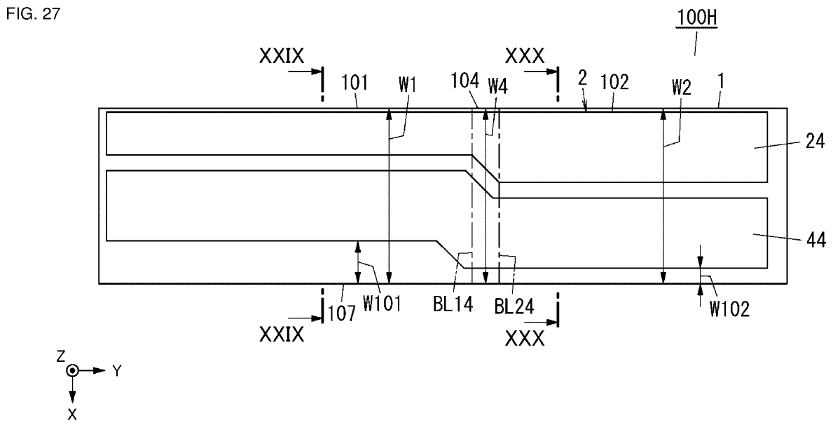

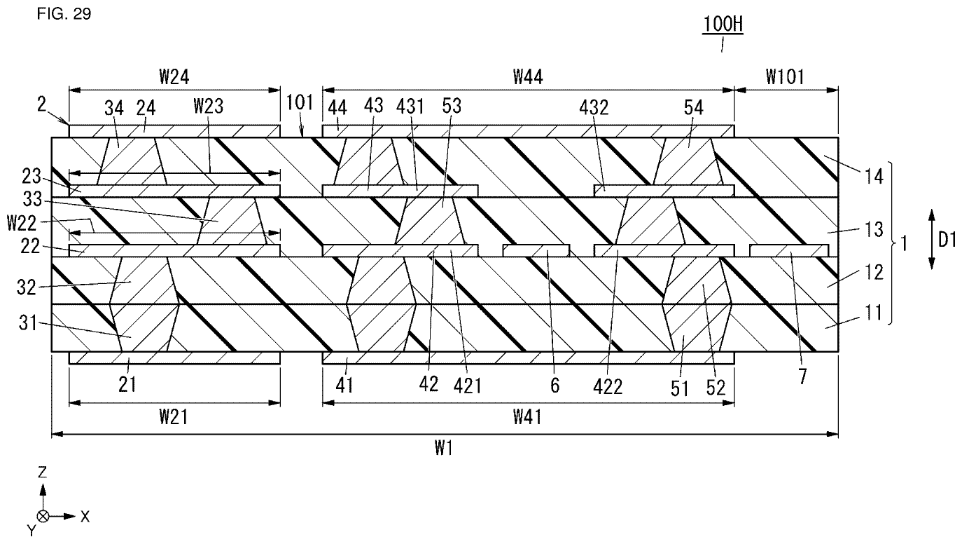

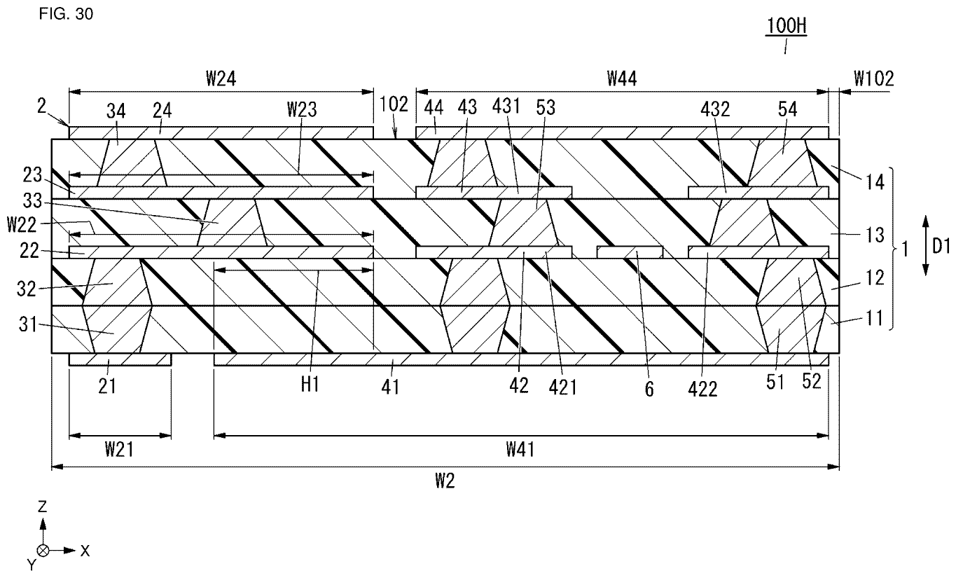

A multilayer substrate 100H according to example embodiment 9 of the present invention is described with reference to FIGS. 27 to 30. For the multilayer substrate 100H according to example embodiment 9, components the same as or similar to those of the multilayer substrate 100F according to example embodiment 7 (see FIGS. 22 to 25) are denoted by the same reference numerals, and description thereof is omitted. In each of FIGS. 27 to 30, similarly to FIGS. 22 to 25, a Cartesian coordinate system having three axes of an X-axis, a Y-axis, and a Z-axis orthogonal or substantially orthogonal to each other is defined, and an axis along the thickness direction D1 (see FIG. 29) of the laminate substrate 1 is indicated as the Z-axis.

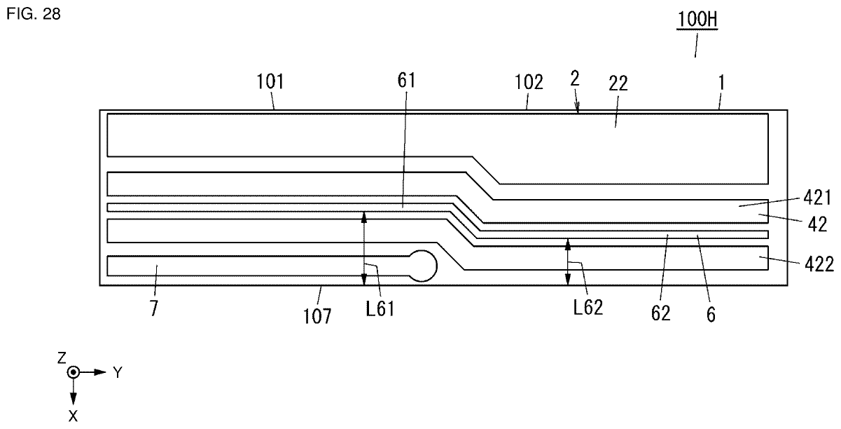

The multilayer substrate 100H according to example embodiment 9 is different from the multilayer substrate 100F according to example embodiment 7 in that the multilayer substrate 100H further includes a signal line 7 disposed in the first transmission line region 101 as shown in FIGS. 28 and 29.

The signal line 7 is located on a side opposite to the alternating current signal line 2 side with respect to the second ground electrode 42. Further, the signal line 7 is located on a side opposite to the RF signal line 6 side with respect to the split ground electrode 422 of the second ground electrode 42 in the width direction of the second signal line 22. Accordingly, in the multilayer substrate 100H, in a direction parallel or substantially parallel to the X-axis, the second signal line 22, the split ground electrode 421, the RF signal line 6, the split ground electrode 422, and the signal line 7 are arranged in order of the second signal line 22, the split ground electrode 421, the RF signal line 6, the split ground electrode 422, and the signal line 7.

A signal different from a signal transmitted through the alternating current signal line 2 is transmitted through the signal line 7. The signal line 7 is, for example, a digital signal line through which a digital signal is transmitted.

The multilayer substrate 100H according to example embodiment 9 can reduce the alternating current resistance similarly to the multilayer substrate 100F according to example embodiment 7.

Further, because the multilayer substrate 100H according to example embodiment 9 includes the signal line 7 separately from the alternating current signal line 2, it is possible to use the multilayer substrate 100H for transmission of a signal by the signal line 7 in addition to transmission of a signal by the alternating current signal line 2.

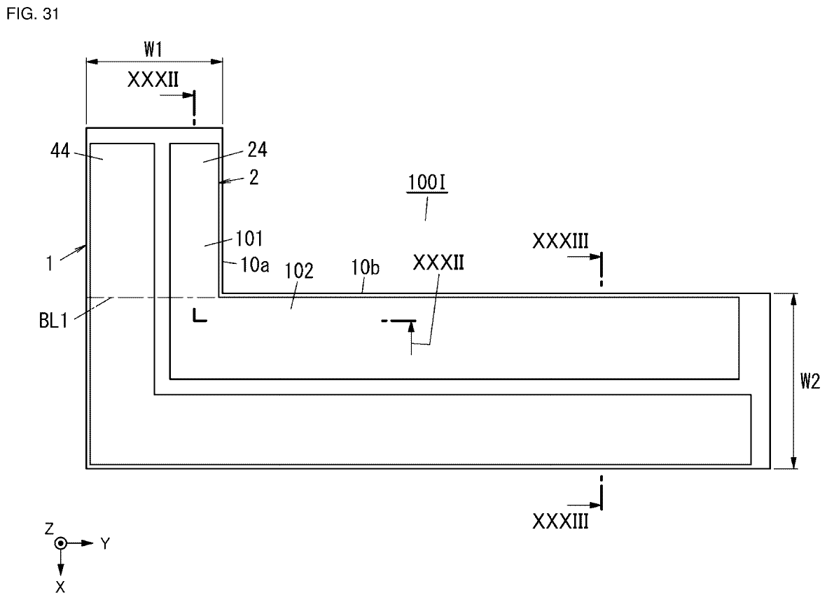

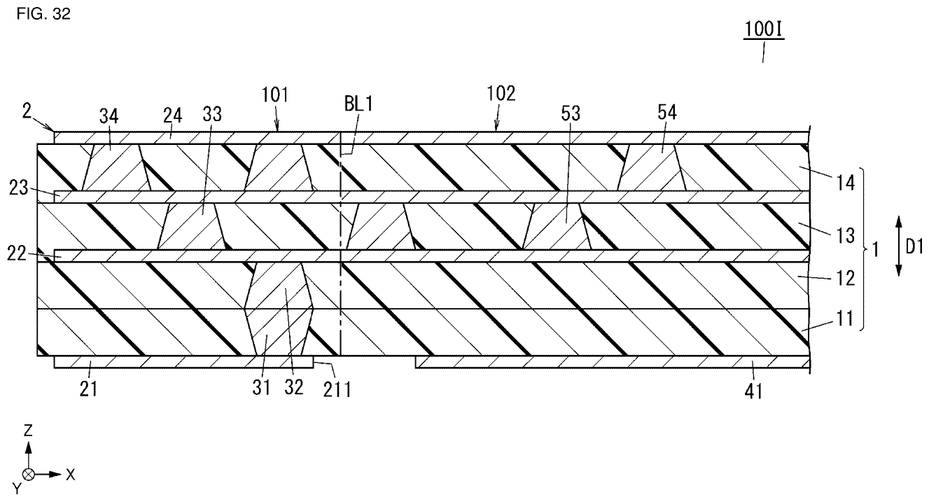

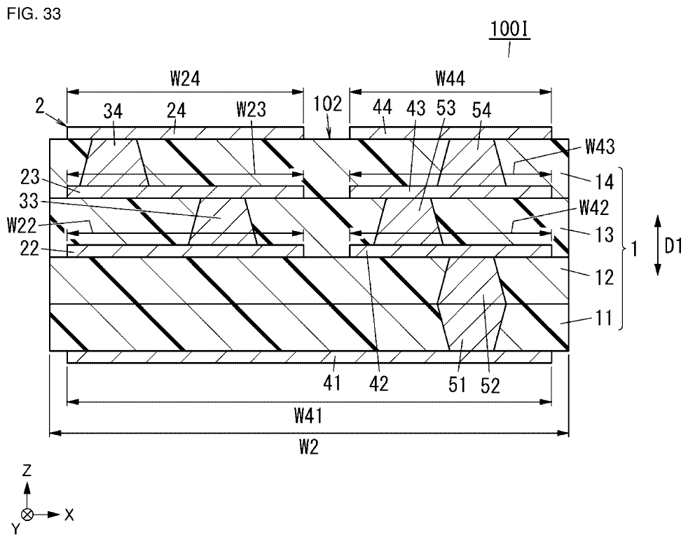

A multilayer substrate 100I according to example embodiment 10 of the present invention is described with reference to FIGS. 31 to 34. For the multilayer substrate 100I according to example embodiment 10, components the same as or similar to those of the multilayer substrate 100B according to example embodiment 3 (see FIGS. 9 to 11) are denoted by the same reference numerals, and description thereof is omitted. In each of FIGS. 31 to 34, similarly to FIGS. 9 to 11, a Cartesian coordinate system having three axes of an X-axis, a Y-axis, and a Z-axis orthogonal or substantially orthogonal to each other is defined, and an axis along the thickness direction D1 (see FIG. 32) of the laminate substrate 1 is indicated as the Z-axis.

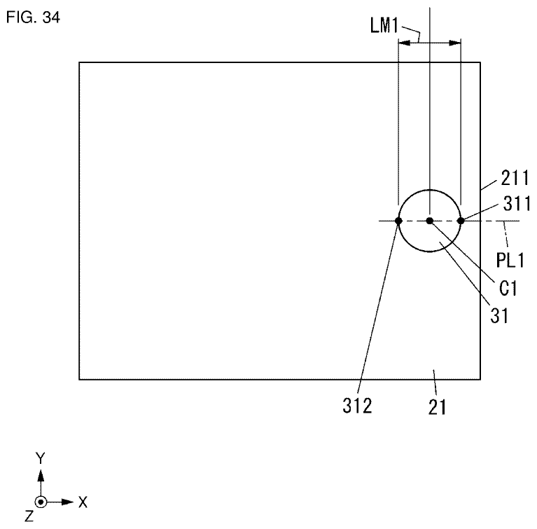

In the multilayer substrate 100I, the first connection conductor 31 among the plurality of connection conductors is disposed at an end portion of the signal line 21 adjacent to one ground electrode 41 in the vicinity of the boundary BL1 between the first transmission line region 101 and the second transmission line region 102. As shown in FIG. 34, when viewed from the thickness direction D1 of the laminate substrate 1, a center C1 of the first connection conductor 31 is present in a range within a maximum length LM1 of the first connection conductor 31 from an edge 211 of the signal line 21. The center C1 of the first connection conductor 31 is located on a perpendicular line PL1 on the edge 211 of the signal line 21 so as to pass through a first point 311 of the first connection conductor 31 that is closest to the edge 211 of the signal line 21. In the first connection conductor 31, a distance between a second point 312 farthest from the edge 211 of the signal line 21 on the perpendicular line PL1 and the center C1 is the same or substantially the same as a distance between the first point 311 and the center C1. The maximum length LM1 is a length between the first point 311 and the second point 312.

The multilayer substrate 100I according to example embodiment 10 can reduce the alternating current resistance similarly to the multilayer substrate 100B according to example embodiment 3.

Further, in the multilayer substrate 100I according to example embodiment 10, the first connection conductor 31 among the plurality of connection conductors is disposed at an end portion of the signal line 21 adjacent to the one ground electrode 41 in the vicinity of the boundary BL1 between the first transmission line region 101 and the second transmission line region 102. When viewed from the thickness direction D1 of the laminate substrate 1, the center C1 of the first connection conductor 31 is present in the range within the maximum length LM1 of the first connection conductor 31 from the edge 211 of the signal line 21.

With the above configuration, the alternating current signal line 2 can be used more effectively in the first transmission line region 101, and the alternating current resistance can be further reduced.

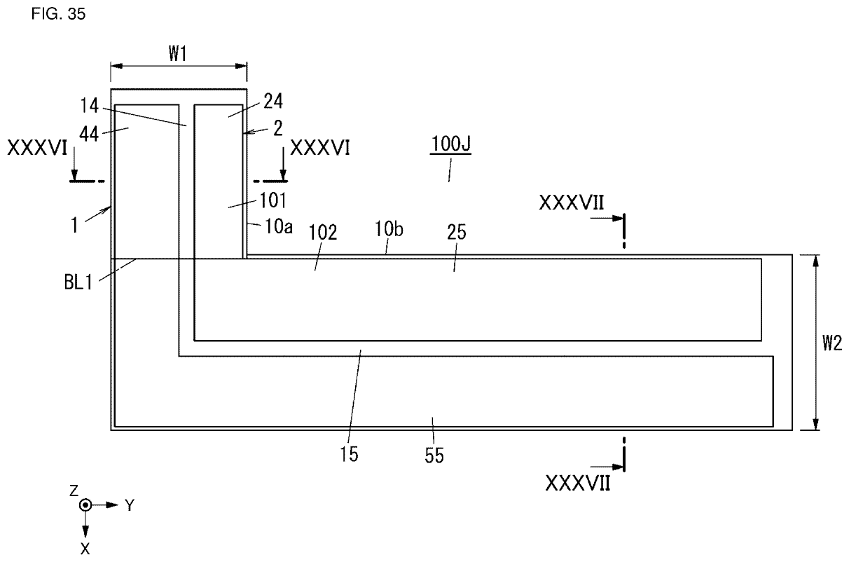

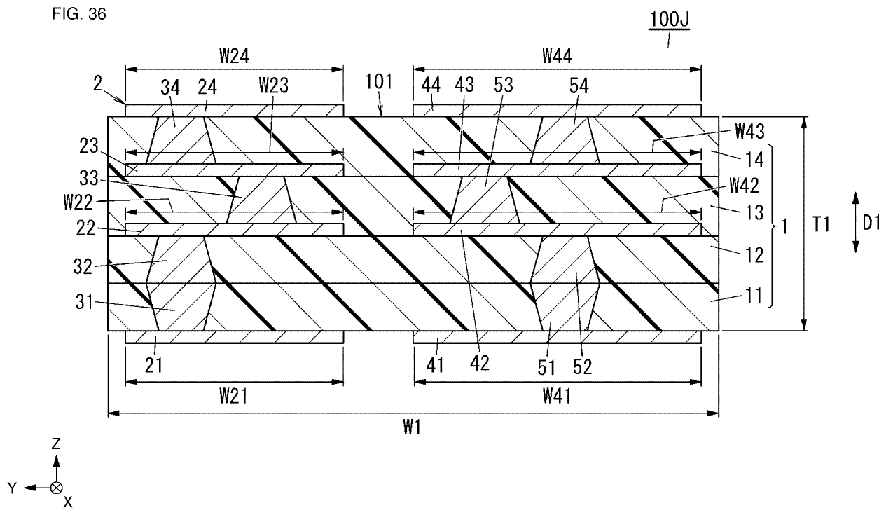

A multilayer substrate 100J according to example embodiment 11 of the present invention is described with reference to FIGS. 35 to 37. For the multilayer substrate 100J according to example embodiment 11, components the same as or similar to those of the multilayer substrate 100 according to example embodiment 1 (see FIGS. 1 to 4) are denoted by the same reference numerals, and description thereof is omitted. In each of FIGS. 35 to 37, similarly to FIGS. 1 to 4, a Cartesian coordinate system having three axes of an X-axis, a Y-axis, and a Z-axis orthogonal or substantially orthogonal to each other is defined, and an axis along the thickness direction D1 (see FIG. 36) of the laminate substrate 1 is indicated as the Z-axis.

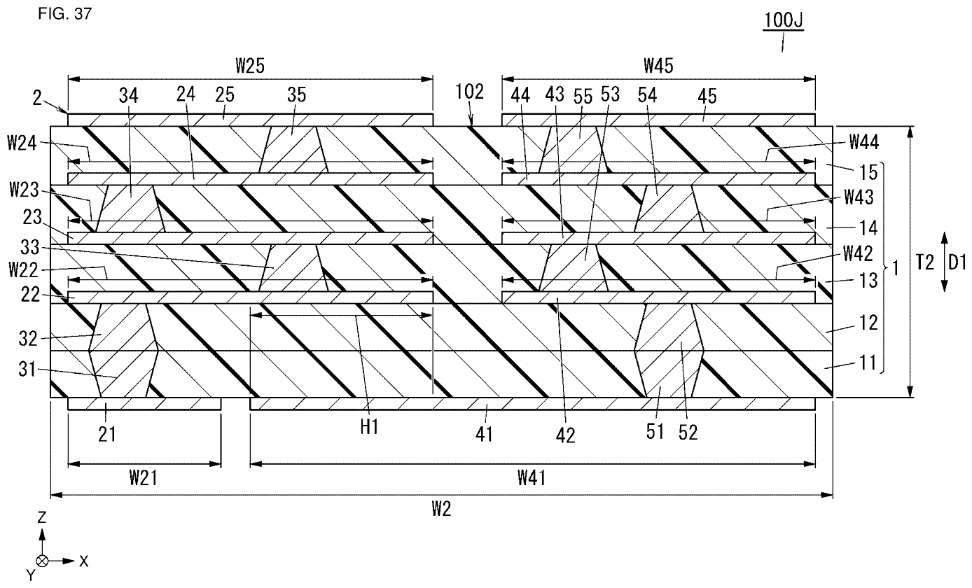

The multilayer substrate 100J according to example embodiment 11 is different from the multilayer substrate 100 according to example embodiment 1 in that a thickness T1 (see FIG. 36) of the first transmission line region 101 in the thickness direction D1 of the laminate substrate 1 is different from a thickness T2 (see FIG. 37) of the second transmission line region 102 in the thickness direction D1 of the laminate substrate 1. In the present example embodiment, the thickness T1 (see FIG. 36) of the first transmission line region 101 in the thickness direction D1 of the laminate substrate 1 is thinner than the thickness T2 (see FIG. 37) of the second transmission line region 102 in the thickness direction D1 of the laminate substrate 1.

In the multilayer substrate 100J, a thickness of the laminate substrate 1 is different between the first transmission line region 101 and the second transmission line region 102. In the first transmission line region 101, the laminate substrate 1 has a multilayer structure including four insulating layers 11 to 14, whereas in the second transmission line region 102, the laminate substrate 1 has a multilayer structure including five insulating layers 11 to 15. The insulating layer 15 is laminated on the insulating layer 14. A material of the insulating layer 15 is the same as a material of the insulating layers 11 to 14. Further, the second transmission line region 102 of the multilayer substrate 100J further includes a signal line 25 and a ground electrode 45 disposed on the insulating layer 15. Further, the second transmission line region 102 further includes a connection conductor 35 that connects the signal line 25 and the signal line 24 and a connection conductor 55 that connects the ground electrode 45 and the ground electrode 44. A material of the signal line 25 is, for example, the same as a material of the other signal lines 21 to 24. In plan view from the thickness direction D1 of the laminate substrate 1, the signal lines 21, 22, 23, 24, and 25 overlap each other. The signal line 25 has a line width W25. A material of the connection conductor 35 is, for example, the same as a material of the first to fourth connection conductors 31 to 34. A material of the ground electrode 45 is, for example, the same as a material of the other ground electrodes 41 to 44. In plan view from the thickness direction D1 of the laminate substrate 1, the ground electrodes 41, 42, 43, 44, and 45 overlap each other. The ground electrode 45 has an electrode width W45. A material of the connection conductor 55 is, for example, the same as a material of the fifth to eighth connection conductors 51 to 54.

The multilayer substrate 100J according to example embodiment 11 can reduce the alternating current resistance similarly to the multilayer substrate 100 according to example embodiment 1.

Further, in the multilayer substrate 100J according to example embodiment 11, the thickness T1 of the first transmission line region 101 in the thickness direction D1 of the laminate substrate 1 is thinner than the thickness T2 of the second transmission line region 102 in the thickness direction D1 of the laminate substrate 1.

With the above configuration, the multilayer substrate 100J is easy to bend in the first transmission line region 101.

The above example embodiments 1 to 11 and the like are merely various example embodiments of the present invention. The above example embodiments 1 to 11 and the like can be variously modified depending on design and the like and may be combined as appropriate as long as the advantageous effects of the present invention can be achieved.

For example, a material of each of the insulating layers 11 to 14 may be polyimide. In this case, each of the first connection conductors 31, the second connection conductors 32, the third connection conductors 33, the fourth connection conductors 34, the fifth connection conductors 51, the sixth connection conductors 52, the seventh connection conductors 53, and the eighth connection conductors 54 may be provided by a through-hole plating layer. Further, the first connection conductor 31 and the second connection conductor 32 connected to each other may be provided by one through-hole plating layer, and the fifth connection conductor 51 and the sixth connection conductor 52 connected to each other may be provided by one through-hole plating layer. A material of the through-hole plating layer is, for example, copper. Further, the laminate substrate 1 may include an adhesive layer interposed between two insulating layers adjacent to each other in the thickness direction D1 of the laminate substrate 1 among the insulating layers 11 to 14.

Further, the multilayer substrates 100, 100A to 100F, and 100H to 100J may be bent in the first transmission line region 101 similarly to the multilayer substrate 100G. Further, the multilayer substrates 100 and 100A to 100J may be bent in the second transmission line region 102.

Further, in the multilayer substrates 100 and 100A to 100I, similarly to the multilayer substrate 100J, the thickness of the first transmission line region 101 in the thickness direction D1 of the laminate substrate 1 may be thinner than the thickness of the second transmission line region 102 in the thickness direction D1 of the laminate substrate 1. Further, in the multilayer substrates 100 and 100A to 100I, the thickness of the second transmission line region 102 may be thinner than the thickness of the first transmission line region 101.

Further, the multilayer substrates 100 and 100A to 100J may be bent in the second transmission line region 102.

Further, the multilayer substrates 100 and 100A to 100J may further include at least one of a first cover layer disposed on one main surface of the laminate substrate 1 or a second cover layer disposed on the other main surface of the laminate substrate 1. Each of the first cover layer and the second cover layer includes, for example, a polyimide film and an adhesive layer. A material of the adhesive layer includes, for example, an acrylic resin, a silicone resin, an epoxy resin, or a urethane resin. If the multilayer substrates 100 and 100A to 100J do not include a bent portion, each of the first cover layer and the second cover layer is not limited to the configuration including the polyimide film and the adhesive layer, and may be, for example, a resist layer. The resist layer can be formed, for example, using a spin coating technique and a photolithography technique.

A multilayer substrate (100; 100A; 100B; 100C; 100D; 100E; 100F; 100G; 100H; 100I; 100J) according to an example embodiment of the present invention includes a laminate substrate (1), an alternating current signal line (2), and a plurality of ground electrodes (41 to 44). A plurality of insulating layers (11 to 14) are laminated in the laminate substrate (1). The alternating current signal line (2) is provided in the laminate substrate (1). The alternating current signal line (2) includes a plurality of signal lines (21 to 24) spaced apart from each other in a thickness direction (D1) of the laminate substrate (1), and the plurality of signal lines (21 to 24) are electrically connected by a plurality of connection conductors that penetrate at least one of the plurality of insulating layers (11 to 14) in the thickness direction (D1). The plurality of ground electrodes (41 to 44) are provided in the laminate substrate (1). The plurality of ground electrodes (41 to 44) are spaced apart from each other in the thickness direction (D1) and are adjacent to the plurality of signal lines (21 to 24) in a width direction of the plurality of signal lines (21 to 24). In a first transmission line region (101) in which a maximum line width of the plurality of signal lines (21 to 24) is smallest, the plurality of signal lines (21 to 24) do not overlap any of the plurality of ground electrodes (41 to 44) in the thickness direction (D1). In a second transmission line region (102) in which the maximum line width of the plurality of signal lines (21 to 24) is largest, one ground electrode (41) among the plurality of ground electrodes (41 to 44) overlaps the signal lines (22 to 24) other than the signal line (21) adjacent to the one ground electrode (41) among the plurality of signal lines (21 to 24).

According to the present example embodiment, the alternating current resistance can be reduced.

In a multilayer substrate (100; 100A; 100B; 100C; 100D; 100E; 100F; 100G; 100H; 100I; 100J) according to an example embodiment of the present invention, in the second transmission line region (102), in the signal line (22) adjacent to the one ground electrode (41) in the thickness direction (D1) among the plurality of signal lines (21 to 24), a region of at least about half in the width direction overlaps the one ground electrode (41) in the thickness direction (D1).

According to the present example embodiment, compared with a case where a region that is less than about half in the width direction in the signal line (22) overlaps the one ground electrode (41) in the thickness direction (D1) of the laminate substrate (1), unevenness of current density in the width direction of the signal lines (22 to 24) can be further reduced, and the alternating current resistance can be further reduced.

I a multilayer substrate (100B) according to an example embodiment of the present invention, in the second transmission line region (102), in the signal line (22) adjacent to the one ground electrode (41) in the thickness direction (D1) among the plurality of signal lines (21 to 24), an entire or substantially an entire region overlaps the one ground electrode (41) in the thickness direction (D1).

According to the present example embodiment, noise resistance can be improved.

In a multilayer substrate (100C; 100D) according to an example embodiment of the present invention, when the maximum line width in the first transmission line region (101) is defined as X1 and the maximum line width in the second transmission line region (102) is defined as X2, the plurality of signal lines (21 to 24) do not overlap any of the plurality of ground electrodes (41 to 44) in the thickness direction (D1) in a third transmission line region (103) in which the maximum line width of the plurality of signal lines (21 to 24) is greater than X1 and less than or equal to (X1+X2)/2.

According to the present example embodiment, it is possible to reduce the alternating current resistance when the alternating current signal line (2) extends across the first transmission line region (101), the second transmission line region (102), and the third transmission line region (103).

In a multilayer substrate (100C) according to an example embodiment of the present invention, an outer shape width (W1) in the width direction of the plurality of signal lines (21 to 24) in the first transmission line region (101) is the same or substantially the same as an outer shape width (W2) in the width direction of the plurality of signal lines (21 to 24) in the second transmission line region (102).

In a multilayer substrate (100; 100A; 100B; 100D; 100E; 100F; 100G; 100H; 100I; 100J) according to an example embodiment of the present invention, an outer shape width (W2) in the width direction of the plurality of signal lines (21 to 24) in the second transmission line region (102) is wider than an outer shape width (W1) in the width direction of the plurality of signal lines (21 to 24) in the first transmission line region (101).

According to the present example embodiment, it is possible to further reduce the alternating current resistance in each of the first transmission line region (101) and the second transmission line region (102) regarding the alternating current signal line (2).

In a multilayer substrate (100) according to an example embodiment of the present invention, a total cross-sectional area of the plurality of signal lines (21 to 24) and the plurality of ground electrodes (41 to 44) in a cross section of the first transmission line region (101) orthogonal or substantially orthogonal to a length direction of the plurality of signal lines (21 to 24) is smaller than a total cross-sectional area of the plurality of signal lines (21 to 24) and the plurality of ground electrodes (41 to 44) in a cross section of the second transmission line region (102) orthogonal or substantially orthogonal to the length direction of the plurality of signal lines (21 to 24).

According to the present example embodiment, the multilayer substrate (100) is easier to bend in the first transmission line region (101) than in the second transmission line region (102).

A multilayer substrate (100G) according to an example embodiment of the present invention is bent in the first transmission line region (101) in any one of the first to seventh aspects.

In a multilayer substrate (100; 100A; 100B; 100C; 100D) according to an example embodiment of the present invention, a material of each of the plurality of insulating layers (11 to 14) includes a thermoplastic resin.

According to the present example embodiment, bendability of the multilayer substrate (100; 100A; 100B; 100C; 100D) can be improved.

A multilayer substrate (100E; 100F; 100G; 100H) according to an example embodiment of the present invention further includes an RF signal line (6. The RF signal line (6) is provided in the laminate substrate (1). The RF signal line (6) extends across the first transmission line region (101) and the second transmission line region (102).

According to the present example embodiment, it is also possible to use the multilayer substrate (100E; 100F; 100G; 100H) for transmission of a high frequency signal by the RF signal line (6) in addition to transmission of a signal by the alternating current signal line (2).

A multilayer substrate (100E) according to an example embodiment of the present invention further includes a third transmission line region (103E) located on a side opposite to the second transmission line region (102) side with respect to the first transmission line region (101) and an RF signal line (6) provided in the laminate substrate (1). The plurality of signal lines (21 to 24) extend across the first transmission line region (101), the second transmission line region (102), and the third transmission line region (103E). The width direction of the plurality of signal lines (21 to 24) in the first transmission line region (101) is orthogonal or substantially orthogonal to the width direction of the plurality of signal lines (21 to 24) in the third transmission line region (103E). The RF signal line (6) includes a first portion (61) in the first transmission line region (101), a second portion (62) in the second transmission line region (102), and a third portion (63) in the third transmission line region (103E). When viewed from the thickness direction (D1) of the laminate substrate (1), a connecting portion (613) between the first portion (61) and the third portion (63) in the RF signal line (6) has a shape curved more gently than an outer edge of the laminate substrate (1).

According to the present example embodiment, impedance deviation of the RF signal line (6) can be reduced or prevented.

A multilayer substrate (100H) according to an example embodiment of the present invention further includes a signal line (7). The signal line (7) is provided only in the first transmission line region (101) among the first transmission line region (101) and the second transmission line region (102).

According to the present example embodiment, it is also possible to use the multilayer substrate (100H) for transmission of another signal by the signal line (7) in addition to transmission of a signal by the alternating current signal line (2).

In a multilayer substrate (100; 100A; 100B; 100C; 100D; 100E; 100F; 100G; 100H; 100I; 100J) according to an example embodiment of the present invention, among the plurality of connection conductors, a connection conductor (first connection conductor 31) disposed on the signal line (21) adjacent to the one ground electrode (41) across a boundary (BL1) between the first transmission line region (101) and the second transmission line region (102) is disposed at an end portion of the signal line (21) adjacent to the one ground electrode (41). When viewed from the thickness direction (D1) of the laminate substrate (1), a center (C1) of the connection conductor (first connection conductor 31) disposed on the signal line (21) adjacent to the one ground electrode (41) is present in a range within a maximum length (LM1) of the connection conductor (first connection conductor 31) from an edge (211) of the signal line (21) adjacent to the one ground electrode (41).

According to the present example embodiment, the alternating current signal line (2) can be used more effectively in the first transmission line region (101), and the alternating current resistance can be further reduced.

In a multilayer substrate (100J) according to an example embodiment of the present invention, a thickness (T1) of the first transmission line region (101) in the thickness direction (D1) of the laminate substrate (1) is different from a thickness (T2) of the second transmission line region (102) in the thickness direction (D1) of the laminate substrate (1).

According to the present example embodiment, it is possible to improve bendability of a thinner one of the first transmission line region (101) and the second transmission line region (102) in the multilayer substrate (100J).

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multilayer substrate comprising:
a laminate substrate including a plurality of insulating layers that are laminated;
an alternating current signal line in the laminate substrate and including a plurality of signal lines spaced apart from each other in a thickness direction of the laminate substrate, the plurality of signal lines being electrically connected by a plurality of connection conductors penetrating one of the plurality of insulating layers in the thickness direction; and
a plurality of ground electrodes in the laminate substrate and being spaced apart from each other in the thickness direction, the plurality of ground electrodes being adjacent to the plurality of signal lines in a width direction of the plurality of signal lines; wherein
in a first transmission line region in which a maximum line width of the plurality of signal lines is smallest, the plurality of signal lines do not overlap any of the plurality of ground electrodes in the thickness direction; and
in a second transmission line region in which the maximum line width of the plurality of signal lines is largest, one ground electrode among the plurality of ground electrodes overlaps a signal line other than a signal line adjacent to the one ground electrode among the plurality of signal lines.

2. The multilayer substrate according to claim 1, wherein,
in the second transmission line region, in a signal line adjacent to the one ground electrode in the thickness direction among the plurality of signal lines, a region of at least about half in the width direction overlaps the one ground electrode in the thickness direction.

3. The multilayer substrate according to claim 1, wherein, in the second transmission line region, in a signal line adjacent to the one ground electrode in the thickness direction among the plurality of signal lines, an entire or substantially an entire region overlaps the one ground electrode in the thickness direction.

4. The multilayer substrate according to claim 1, wherein, when the maximum line width in the first transmission line region is defined as X1 and the maximum line width in the second transmission line region is defined as X2, the plurality of signal lines do not overlap any of the plurality of ground electrodes in the thickness direction in a third transmission line region in which the maximum line width of the plurality of signal lines is greater than X1 and less than or equal to (X1+X2)/2.

5. The multilayer substrate according to claim 1, wherein an outer shape width in the width direction of the plurality of signal lines in the first transmission line region is the same as an outer shape width in the width direction of the plurality of signal lines in the second transmission line region.

6. The multilayer substrate according to claim 1, wherein an outer shape width in the width direction of the plurality of signal lines in the second transmission line region is wider than an outer shape width in the width direction of the plurality of signal lines in the first transmission line region.

7. The multilayer substrate according to claim 1, wherein a total cross-sectional area of the plurality of signal lines and the plurality of ground electrodes in a cross section of the first transmission line region orthogonal or substantially orthogonal to a length direction of the plurality of signal lines is smaller than a total cross-sectional area of the plurality of signal lines and the plurality of ground electrodes in a cross section of the second transmission line region orthogonal to the length direction of the plurality of signal lines.

8. The multilayer substrate according to claim 1, wherein the multilayer substrate is bent in the first transmission line region.

9. The multilayer substrate according to claim 1, wherein a material of each of the plurality of insulating layers includes a thermoplastic resin.

10. The multilayer substrate according to claim 1, further comprising:
an RF signal line in the laminate substrate; wherein
the RF signal line extends across the first transmission line region and the second transmission line region.

11. The multilayer substrate according to claim 1, further comprising:
a third transmission line region located on a side opposite to the second transmission line region side with respect to the first transmission line region; and
an RF signal line in the laminate substrate; wherein the plurality of signal lines extend across the first transmission line region, the second transmission line region, and the third transmission line region;
the width direction of the plurality of signal lines in the first transmission line region is orthogonal or substantially orthogonal to the width direction of the plurality of signal lines in the third transmission line region;
the RF signal line includes a first portion in the first transmission line region, a second portion in the second transmission line region, and a third portion in the third transmission line region; and
when viewed from the thickness direction of the laminate substrate, a connecting portion between the first portion and the third portion in the RF signal line has a shape curved more gently than an outer edge of the laminate substrate.

12. The multilayer substrate according to claim 1, further comprising a signal line located only in the first transmission line region among the first transmission line region and the second transmission line region.

13. The multilayer substrate according to claim 1, wherein
among the plurality of connection conductors, a connection conductor on the signal line adjacent to the one ground electrode across a boundary between the first transmission line region and the second transmission line region is located at an end portion of the signal line adjacent to the one ground electrode; and
when viewed from the thickness direction of the laminate substrate, a center of the connection conductor on the signal line adjacent to the one ground electrode is present in a range within a maximum length of the connection conductor from an edge of the signal line adjacent to the one ground electrode.

14. The multilayer substrate according to claim 1, wherein a thickness of the first transmission line region in the thickness direction of the laminate substrate is different from a thickness of the second transmission line region in the thickness direction of the laminate substrate.

15. The multilayer substrate according to claim 9, wherein the thermoplastic resin includes a liquid crystal polymer of polytetrafluoroethylene.

16. The multilayer substrate according to claim 1, wherein a thickness of each of the plurality of insulating layers is about 10 μm or more and about 120 μm or less.

17. The multilayer substrate according to claim 1, wherein the laminate substrate has an L-shape in a plan view from the thickness direction.

18. The multilayer substrate according to claim 1, wherein a thickness of each of the plurality of signal lines is about 3 μm or more and about 40 μm or less.

19. The multilayer substrate according to claim 1, wherein each of the plurality of signal lines has an L-shape in a plan view from the thickness direction.

20. The multilayer substrate according to claim 1, wherein each of the plurality of signal lines includes a patterned copper foil.
